(19) United States
(12) Patent Application Publication
(10) Pub. No.: US 2025/0329572 A1
(43) Pub. Date: Oct. 23, 2025

(54) APPARATUS FOR MANUFACTURING DISPLAY DEVICE AND METHOD OF MANUFACTURING DISPLAY DEVICE

(71) Applicant: Samsung Display Co., LTD., Yongin-si (KR)

(72) Inventors: Jae Woo LEE, Yongin-si (KR); Min Chan KIM, Yongin-si (KR); Sung Jin KIM, Yongin-si (KR); Min Ho BAE, Yongin-si (KR); Jae Won SHIM, Yongin-si (KR)

(21) Appl. No.: 19/004,394

(22) Filed: Dec. 29, 2024

(30) Foreign Application Priority Data
Apr. 17, 2024 (KR) 10-2024-0051497

(51) Int. Cl. H01L 21/687; H01L 21/68; H01L 21/683; H10K 59/12; H10K 71/80

(52) U.S. Cl. CPC H01L 21/68785; H01L 21/681; H01L 21/6831; H10K 59/1201; H10K 71/80

(57) ABSTRACT

An apparatus for manufacturing a display device includes an alignment unit, a carrier disposed on the alignment unit, where the carrier includes an accommodating portion in which a wafer is accommodated, a pressing unit disposed on the carrier, a first vision device disposed on one side of the pressing unit on the carrier, and a controller which controls an alignment of the wafer and the carrier.

This application claims priority to Korean Patent Application No. 10-2024-0051497, filed on Apr. 17, 2024, and all the benefits accruing therefrom under 35 U.S.C. § 119, the content of which in its entirety is herein incorporated by reference.

### BACKGROUND

### 1. Field

Embodiments of the disclosure relate to an apparatus for manufacturing a display device and a method of manufacturing a display device.

### 2. Description of the Related Art

Recently, due to the development of electronic devices and display devices capable of implementing extended reality, the interest in the extended reality is increasing. The extended reality includes virtual reality (VR), augmented reality (AR), and mixed reality (MR).

Various display devices are emerging to implement the extended reality. For example, a head mounted display (HMD) and AR glasses are examples of display devices for implementing extended reality.

Recently, research on small displays is actively being conducted due to the trend toward weight reduction and miniaturization. Examples of small displays or electronic devices including the same include a smart watch, a watch phone, a head-up display (HUD) in automobiles, and an Internet-of-Things (IoT) device.

The display device for implementing the extended reality may be provided in a compact manner and disposed close to a user's eyes to enlarge and display a video or an image using a plurality of lenses. Further, also in the case of small displays, it may be desired to display a large amount of information on a small screen and provide a clear video or image. Therefore, the display devices and the small displays for implementing extended reality need to provide high-resolution images, e.g., images with a resolution of 3000 pixels per inch (PPI) or higher.

To this end, an organic light emitting diode on silicon (OLEDoS), which is a high-resolution small-sized organic light emitting display device, is used. The OLEDoS is an image display device in which an organic light emitting diode (OLED) is disposed on a semiconductor wafer substrate including complementary metal oxide semiconductor (CMOS).

### SUMMARY

Embodiments of the disclosure provide an apparatus for manufacturing a display device that includes a carrier accommodating a wafer so that display process equipment using a conventional mother substrate may be utilized in a display process using a wafer, and a method of manufacturing a display device.

Embodiments of the disclosure also provide an apparatus for manufacturing a display device in which alignment accuracy between a carrier and a wafer is improved, and a method of manufacturing a display device.

Embodiments of the disclosure also provide an apparatus for manufacturing a display device in which damage to a wafer is minimized when the wafer is detached from a carrier, and a method of manufacturing a display device.

However, embodiments of the disclosure are not restricted to those set forth herein. The above and other embodiments of the disclosure will become more apparent to one of ordinary skill in the art to which the disclosure pertains by referencing the detailed description of embodiments of the disclosure given below.

According to an embodiment of the disclosure, an apparatus for manufacturing a display device includes an alignment unit, a carrier disposed on the alignment unit, where the carrier includes an accommodating portion in which a wafer is accommodated, a pressing unit disposed on the carrier, a first vision device disposed on one side of the pressing unit on the carrier, and a controller which controls an alignment of the wafer and the carrier.

In an embodiment, the carrier may further include a first alignment mark disposed on one side of the accommodating portion, and the first vision device may capture images of the first alignment mark of the carrier and a second alignment mark of the wafer.

In an embodiment, the first vision device may include a camera, and a number of the camera in the first vision device may be equal to a number of the first alignment mark in the carrier.

In an embodiment, the carrier may further include a coupling portion disposed on a bottom surface of the accommodating portion, the coupling portion may be disposed between the wafer and the carrier, and the wafer and the carrier may be coupled to each other by the coupling portion.

In an embodiment, the coupling portion may include a sticky chuck or an electrostatic chuck.

In an embodiment, the carrier may further include a buffer portion disposed on a portion of the bottom surface of the accommodating portion other than a portion where the coupling portion is disposed, and a step compensation portion disposed below the coupling portion, where a thickness of the buffer portion may be equal to a sum of a thickness of the coupling portion and a thickness of the step compensation portion.

In an embodiment, the alignment unit may includes a pin extending in a direction toward the carrier, a pin hole may be defined through the carrier in a lower portion of the accommodating portion, and the pin may move through the pin hole.

In an embodiment, the wafer may be mounted on the pin.

In an embodiment, the alignment unit may further include a pin driver disposed below the pin, and the pin driver may include a vertical driver and a rotational driver.

In an embodiment, the alignment unit may further include a first pressure sensor disposed below the pin, and the first pressure sensor may measure a pressing force applied thereto when detaching the wafer from the carrier.

In an embodiment, the pin may be provided in plurality, and the first pressure sensor may be provide in plurality in a one-to-one correspondence with the plurality of pins.

In an embodiment, the pressing unit may include, a pressing part disposed on a first surface facing the carrier, and a second pressure sensor disposed between the first surface and the pressing part, and the second pressure sensor may measure a pressing force applied thereto when coupling the carrier and the wafer to each other.

In an embodiment, the first vision device may capture a first image after a primary alignment of the wafer and before a primary pressing of the wafer, and capture a second image after the primary pressing of the wafer, the controller may include an alignment correction value calculation unit, where the alignment correction value calculation unit may calculate a correction value by comparing the first image with the second image, and the alignment unit may align the wafer to be shifted by the correction value during a secondary pressing of the wafer.

In an embodiment, the apparatus may further include a second vision device disposed on the carrier, where the second vision device may capture images of the carrier and the alignment unit.

In an embodiment, the apparatus may further include a carrier transfer unit which positions the carrier on the alignment unit.

In an embodiment, the apparatus may further include a wafer transfer unit which positions the wafer on the carrier.

In an embodiment, the controller may include an alignment processing unit, the alignment processing unit may provide a driving signal to the wafer transfer unit, the wafer transfer unit may position the wafer on the carrier based on the driving signal, the first vision device may provide captured images of the carrier and the wafer to the alignment processing unit, and the alignment processing unit may provide the driving signal again to the wafer transfer unit based on the captured images to align the wafer with the carrier in real time.

In an embodiment, in a plan view, the carrier may haver a quadrilateral shape, and the wafer may have a circular shape.

According to an embodiment of the disclosure, a method of manufacturing a display device includes performing a primary alignment process including aligning a wafer with a reference point of a carrier, performing a wafer primary pressing process including pressing the wafer, performing a primary distortion inspection process including measuring a first degree of distortion of the wafer and the carrier, performing a detachment process including detaching the wafer from the carrier, a secondary alignment process including aligning the wafer with the carrier, performing a wafer secondary pressing process including pressing the wafer, and performing a secondary distortion inspection process including measuring a second degree of distortion of the wafer and the carrier, where the performing the secondary alignment process includes aligning the wafer to be shifted from the reference point by a correction value by using the first degree of distortion measured in the primary distortion inspection process as the correction value.

In an embodiment, when the second degree of distortion is smaller than or equal to a threshold in the secondary distortion inspection process, the method may be ended.

In an embodiment, when the second degree of distortion exceeds a threshold in the secondary distortion inspection process, the method may further includes performing a correction value recalculation and wafer realignment process including recalculating the correction value and realigning the wafer is further performed.

In an embodiment, the performing the correction value recalculation and wafer realignment process may include, performing a correction value recalculation process including recalculating the correction value, performing a wafer realignment process including realigning the wafer, performing a process including re-pressing the wafer, and performing a distortion re-inspection process including measuring a third degree of distortion of the wafer and the carrier.

In an embodiment, the correction value recalculation process may include calculating a correction value of a current wafer using correction values of previous wafers.

In an embodiment, when the third degree of distortion is smaller than or equal to a threshold in the distortion re-inspection process, the method of manufacturing the display device may be ended.

In an embodiment, when the third degree of distortion exceeds a threshold in the distortion re-inspection process, the method may further include performing the correction value recalculation and wafer realignment process again.

In an embodiment, each of correction values of previous wafers may include at least one sub-correction value, and a number of sub-correction values in the correction values of the previous wafers is equal to a number of repetitions of the performing the correction value recalculation process.

In an embodiment, a final sub-correction value among the sub-correction values in each correction value of the previous wafers may be a correction value of the previous wafers.

In an embodiment, in each of the performing the wafer primary pressing process and the performing the wafer secondary pressing process, a combined pressing force may be corrected in real time based on a pressing force measured by a pressure sensor.

In an embodiment, in the performing the detachment process including the detaching the wafer from the carrier, a detachment pressing force may be corrected in real time based on a pressing force measured by a pressure sensor.

According to an aspect of the present disclosure, there is provided an electronic device comprising a head mounted display device manufactured by the apparatus of claim 1, wherein the head mounted display device comprises, at least one display device, a display device housing configured to accommodate the at least one display device, and an optical member configured to magnify a display image of the at least one display device or change an optical path, wherein the at least one display device comprises, a semiconductor substrate, a plurality of conductive layers sequentially stacked on the semiconductor substrate, and a plurality of light emitting elements on the plurality of conductive layers.

According to an aspect of the present disclosure, there is provided an electronic device comprising a head mounted display device manufactured by the method of claim 19, wherein the head mounted display device comprises, at least one display device, a display device housing configured to accommodate the at least one display device, and an optical member configured to magnify a display image of the at least one display device or change an optical path, wherein the at least one display device comprises, a semiconductor substrate, a plurality of conductive layers sequentially stacked on the semiconductor substrate, and a plurality of light emitting elements on the plurality of conductive layers.

In accordance with embodiments of the apparatus for manufacturing a display device and the method of manufacturing a display device, a carrier accommodating a wafer may be provided in a way such that a display manufacturing process equipment using a conventional mother substrate may be utilized in a display manufacturing process using a wafer.

In accordance with embodiments of the apparatus for manufacturing a display device and the method of manufacturing a display, the alignment accuracy of the carrier and the wafer may be improved.

In accordance with embodiments of the apparatus for manufacturing a display device and the method of manufacturing a display device, damage to the wafer may be minimized when the wafer is detached from the carrier.

However, effects according to the embodiments of the disclosure are not limited to those exemplified above and various other effects are incorporated herein.

### BRIEF DESCRIPTION OF THE DRAWINGS

The above and other features of embodiments of the disclosure will become more apparent by describing in detail embodiments thereof with reference to the attached drawings, in which:

FIG. 1 is an exploded perspective view showing a display device according to an embodiment;

FIG. 2 is a block diagram illustrating a display device according to an embodiment;

FIG. 3 is an equivalent circuit diagram of a first sub-pixel according to an embodiment;

FIG. 4 is a plan view illustrating an example of a display panel according to an embodiment;

FIGS. 5 and 6 are plan views illustrating embodiments of the display area of FIG. 4;

FIG. 7 is a cross-sectional view illustrating an example of a display panel taken along line X1-X1′ of FIG. 5;

FIG. 8 is an exploded perspective view illustrating a head mounted display according to an embodiment;

FIG. 9 is a perspective view showing an augmented reality content providing device according to an embodiment;

FIG. 10A is a rear exploded perspective view of the augmented reality content providing device of FIG. 9;

FIG. 10B is a front exploded perspective view of the augmented reality content providing device of FIG. 9;

FIG. 11 is a perspective view showing an apparatus for manufacturing a display device according to an embodiment;

FIG. 12 is a cross-sectional view showing an apparatus for manufacturing a display device according to an embodiment;

FIG. 13 is a perspective view showing a carrier according to an embodiment;

FIG. 14 is a cross-sectional view showing the carrier taken along line X2-X2′ of FIG. 13;

FIG. 15 is a block diagram showing a controller according to an embodiment;

FIG. 16 is a flowchart showing a method of manufacturing a display device according to an embodiment;

FIG. 17 is a cross-sectional view showing process S100 of FIG. 16;

FIGS. 18 and 19 are cross-sectional views showing process S200 of FIG. 16;

FIGS. 20 and 21 are cross-sectional views showing process S300 of FIG. 16;

FIG. 22 is a cross-sectional view showing process S400 of FIG. 16;

FIG. 23 is a plan view illustrating a method of measuring a degree of distortion of a wafer;

FIG. 24 is a cross-sectional view showing process S500 of FIG. 16;

FIGS. 25 and 26 are cross-sectional views showing process S600 of FIG. 16;

FIG. 27 is a schematic diagram illustrating alignment correction data processed by a controller;

FIG. 28 is a cross-sectional view showing process S700 of FIG. 16;

FIG. 29 is a cross-sectional view showing process S800 of FIG. 16; and

FIG. 30 is a cross-sectional view showing process S900 of FIG. 16.

### DETAILED DESCRIPTION

The invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will also be understood that when a layer is referred to as being “on” another layer or substrate, it can be directly on the other layer or substrate, or intervening layers may also be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings.

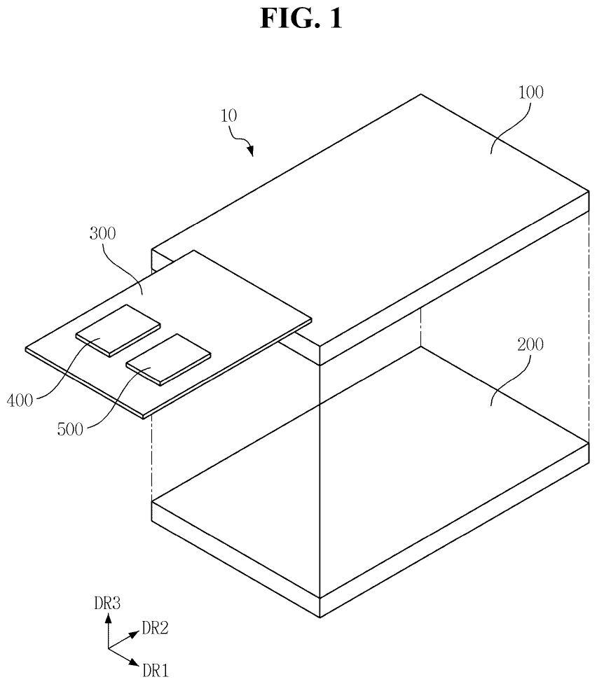

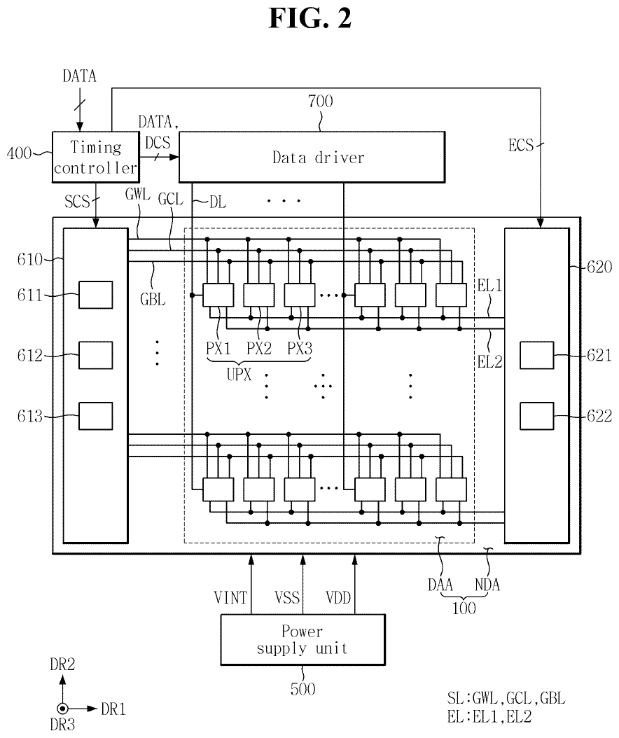

FIG. 1 is an exploded perspective view showing a display device according to an embodiment. FIG. 2 is a block diagram illustrating a display device according to an embodiment.

Referring to FIGS. 1 and 2, a display device 10 according to an embodiment may be a device displaying a moving image or a still image. The display device 10 according to an embodiment may be applied to portable electronic devices such as a mobile phone, a smartphone, a tablet personal computer (PC), a mobile communication terminal, an electronic organizer, an electronic book, a portable multimedia player (PMP), a navigation system, an ultra mobile PC (UMPC) or the like. For example, the display device 10 according to an embodiment may be applied as a display unit of a television, a laptop, a monitor, a billboard, or an Internet-of-Things (IoT) terminal. Alternatively, the display device 10 according to an embodiment may be applied to a smart watch, a watch phone, a head mounted display (HMD) for implementing virtual reality and augmented reality, and the like.

The display device 10 according to an embodiment may include a display panel 100, a heat dissipation layer 200, a circuit board 300, a timing control circuit 400, and a power supply circuit 500.

The display panel 100 may have a planar shape similar to a quadrilateral shape. In an embodiment, for example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the embodiment of the disclosure is not limited thereto.

In the figures, the first direction DR1 and the second direction DR2 cross each other as horizontal directions. For example, the first direction DR1 and the second direction DR2 are orthogonal to each other. In addition, a third direction DR3 crosses the first direction DR1 and the second direction DR2, and the first to third direction DR1 to DR3 are, for example, perpendicular directions orthogonal to each other. Unless otherwise defined, in the disclosure, directions indicated by arrows of the first to third directions DR1, DR2, and DR3 are referred to as one side, and the opposite directions thereto are referred to as the other side. Here, the third direction Dr3 may be a thickness direction of the display panel 100. Also, the terms “above,” “upper side,” “upper portion,” “top,” and “top surface,” as used herein, refer to a direction indicated by an arrow in the drawing in the third direction DR3 based on the drawings, and the terms “below,” “lower side,” “lower portion,” “bottom,” and “bottom surface,” as used herein, refer to a direction opposite to the direction indicated by the arrow in the third direction DR3 based on the drawings.

The display panel 100 may include a display area DAA in which an image is displayed and a non-display area NDA in which no image is displayed, as shown in FIG. 2.

The display area DAA may include a plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of scan lines SL and the plurality of emission control lines EL may extend in the first direction DR1, while being disposed or arranged in the second direction DR2. The plurality of data lines DL may extend in the second direction DR2, while being disposed or arranged in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

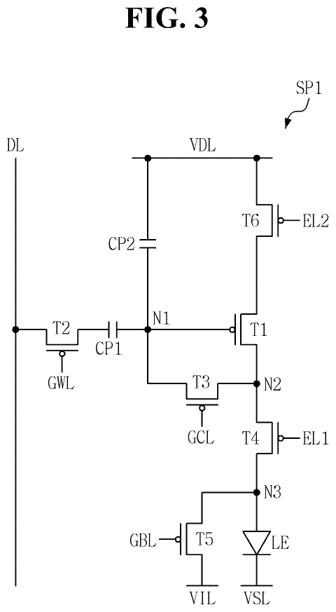

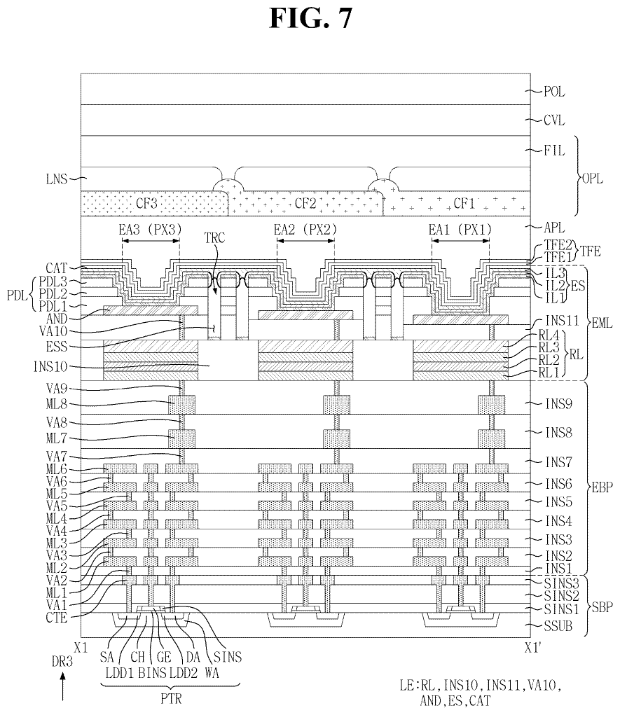

The plurality of pixels PX may include a plurality of sub-pixels SP1, SP2, and SP3. The plurality of sub-pixels SP1, SP2, and SP3 may include a plurality of pixel transistors as shown in FIG. 3 to be described later, and the plurality of pixel transistors may be formed by a semiconductor process and disposed on a semiconductor substrate SSUB (See FIG. 7). In an embodiment, for example, the plurality of pixel transistors of a data driver 700 may include or be formed of complementary metal oxide semiconductor (CMOS).

Each of the plurality of sub-pixels SP1, SP2, and SP3 may be connected to a corresponding one write scan line GWL among the plurality of write scan lines GWL, a corresponding one control scan line GCL among the plurality of control scan lines GCL, a corresponding one bias scan line GBL among the plurality of bias scan lines GBL, a corresponding one first emission control line EL1 among the plurality of first emission control lines EL1, a corresponding one second emission control line EL2 among the plurality of second emission control lines EL2, and a corresponding one data line DL among the plurality of data lines DL. Each of the plurality of sub-pixels SP1, SP2, and SP3 may receive a data voltage of the data line DL in response to a write scan signal of the write scan line GWL, and emit light from the light emitting element based on the data voltage.

The non-display area NDA may include a scan driver 610, an emission driver 620, and the data driver 700.

The scan driver 610 includes a plurality of scan transistors, and the emission driver 620 includes a plurality of light emitting transistors. The plurality of scan transistors and the plurality of light emitting transistors may be formed through a semiconductor process, and disposed on the semiconductor substrate SSUB (see FIG. 7). In an embodiment, for example, the plurality of scan transistors and the plurality of light emitting transistors may include or be formed of CMOS. Although FIG. 2 an embodiment where the scan driver 610 is disposed on the left side of the display area DAA and the emission driver 620 is disposed on the right side of the display area DAA, the disclosure is not limited thereto. In another embodiment, for example, the scan driver 610 and the emission driver 620 may be disposed on both the left side and the right side of the display area DAA.

The scan driver 610 includes a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals in response to the scan timing control signal SCS of the timing control circuit 400 and output the write scan signals sequentially to the write scan lines GWL. The control scan signal output unit 612 may generate control scan signals in response to the scan timing control signal SCS and sequentially output the control scan signals to the control scan lines GCL. The bias scan signal output unit 613 may generate bias scan signals in response to the scan timing control signal SCS and output the bias scan signals sequentially to bias scan lines EBL.

The emission driver 620 includes a first emission control driver 621 and a second emission control driver 622. Each of the first emission control driver 621 and the second emission control driver 622 may receive the emission timing control signal ECS from the timing control circuit 400. The first emission control driver 621 may generate first emission control signals in response to the emission timing control signal ECS and sequentially output the first emission control signals to the first emission control lines EL1. The second emission control driver 622 may generate second emission control signals in response to the emission timing control signal ECS and sequentially output the second emission control signals to the second emission control lines EL2.

The data driver 700 may include a plurality of data transistors, and the plurality of data transistors may be formed through a semiconductor process, and disposed on the semiconductor substrate SSUB (see FIG. 7). In an embodiment, for example, the plurality of data transistors may include or be formed of CMOS.

The data driver 700 may receive digital video data DATA and a data timing control signal DCS from the timing control circuit 400. The data driver 700 may convert the digital video data DATA into analog data voltages based on the data timing control signal DCS and output the analog data voltages to the data lines DL. In this case, the sub-pixels SP1, SP2, and SP3 are selected by the write scan signal of the scan driver 610, and data voltages may be supplied to the selected sub-pixels SP1, SP2, and SP3.

The heat dissipation layer 200 may overlap the display panel 100 in the third direction DR3, which is the thickness direction of the display panel 100. The heat dissipation layer 200 may be disposed on one surface of the display panel 100, for example, on the rear surface thereof. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

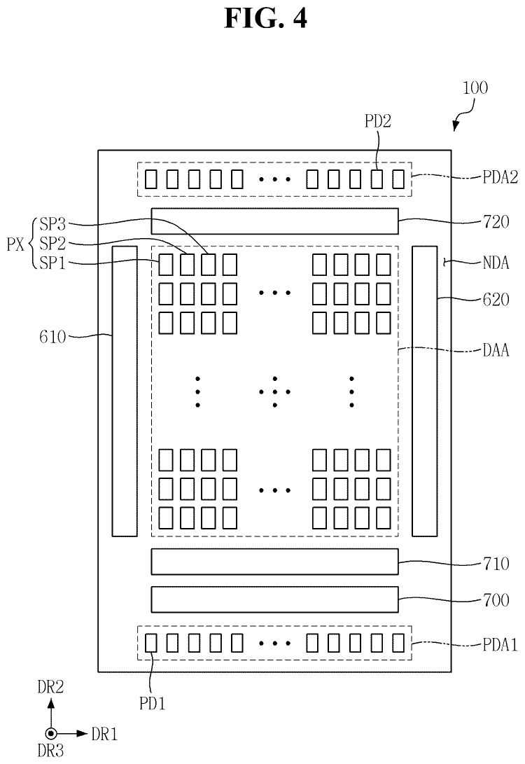

The circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. In an embodiment, the circuit board 300 may be in an unfolded state as shown in FIG. 1, or the circuit board 300 may be bent. In a bent state, one end of the circuit board 300 may be disposed on the rear surface of the display panel 100 and/or the rear surface of the heat dissipation layer 200. One end of the circuit board 300 may be an opposite end of the other end of the circuit board 300 connected to the plurality of first pads PD1 (see FIG. 4) of the first pad portion PDA1 (see FIG. 4) of the display panel 100 by using a conductive adhesive member.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. In an embodiment, for example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to one surface of the circuit board 300. In an embodiment, the scan timing control signal SCS, the emission timing control signal ECS, digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be disposed in the non-display area NDA of the display panel 100, similarly to the scan driver 610, the emission driver 620, and the data driver 700. In such an embodiment, the timing control circuit 400 may include a plurality of timing transistors, and each power supply circuit 500 may include a plurality of power transistors. The plurality of timing transistors and the plurality of power transistors may be formed through a semiconductor process, and disposed on the semiconductor substrate SSUB (see FIG. 7). In an embodiment, for example, the plurality of timing transistors and the plurality of power transistors may include or be formed of CMOS. Each of the timing control circuit 400 and the power supply circuit 500 may be disposed between the data driver 700 and the first pad portion PDA1 (see FIG. 4).

FIG. 3 is an equivalent circuit diagram of a first sub-pixel according to an embodiment.

Referring to FIG. 3 in addition to FIGS. 1 and 2, in an embodiment, a first sub-pixel SP1 of each pixel may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In such an embodiment, the first driving voltage VSS may be lower than the third driving voltage VINT. In such an embodiment, the second driving voltage VDD may be higher than the third driving voltage VINT.

The first sub-pixel SP1 may include a plurality of transistors T1 to T6, a light emitting element LE, a first capacitor CP1, and a second capacitor CP2.

The light emitting element LE may emit light in response to a driving current (source-drain current) flowing through the channel of a first transistor T1. A light emission amount of the light emitting element LE may be proportional to the driving current. The light emitting element LE may be disposed between a fourth transistor T4 and the first driving voltage line VSL. The first electrode of the light emitting element LE may be connected to the drain electrode of the fourth transistor T4, and the second electrode thereof may be connected to the first driving voltage line VSL. In an embodiment, the first electrode of the light emitting element LE may be an anode electrode, and the second electrode of the light emitting element LE may be a cathode electrode. In an embodiment, the light emitting element LE may be an organic light emitting diode including a first electrode, a second electrode, and an organic light emitting layer disposed between the first electrode and the second electrode, but the embodiment of the disclosure is not limited thereto. In another embodiment, for example, the light emitting element LE may be an inorganic light emitting element including a first electrode, a second electrode, and an inorganic semiconductor disposed between the first electrode and the second electrode, and the light emitting element LE may be, e.g., a micro light emitting diode.

The first transistor T1 may be a driving transistor that controls a driving current flowing between the source electrode and the drain electrode thereof based on a voltage applied to the gate electrode thereof. The first transistor T1 may include a gate electrode connected to a first node N1, a source electrode connected to the drain electrode of a sixth transistor T6, and a drain electrode connected to a second node N2.

A second transistor T2 may be disposed between one electrode of the first capacitor CP1 and the data line DL. The second transistor T2 may be turned on by the write scan signal of the write scan line GWL to connect the one electrode of the first capacitor CP1 to the data line DL. Accordingly, when the second transistor T2 is turned on, the data voltage of the data line DL may be applied to the one electrode of the first capacitor CP1. The second transistor T2 may include a gate electrode connected to the write scan line GWL, a source electrode connected to the data line DL, and a drain electrode connected to the one electrode of the first capacitor CP1.

A third transistor T3 may be disposed between the first node N1 and the second node N2. The third transistor T3 may be turned on by the write control signal of the control scan line GCL to connect the first node N1 to the second node N2. In such an embodiment, when the third transistor T3 is turned on, the gate electrode and the source electrode of the first transistor T1 are connected to each other, such that the first transistor T1 may operate like a diode. The third transistor T3 may include a gate electrode connected to the control scan line GCL, a source electrode connected to the second node N2, and a drain electrode connected to the first node N1.

The fourth transistor T4 may be connected between the second node N2 and a third node N3. The fourth transistor T4 may be turned on by the first emission control signal of the first emission control line EL1 to connect the second node N2 to the third node N3. Accordingly, when the fourth transistor T4 is turned on, the driving current of the first transistor T1 may be supplied to the light emitting element LE. The fourth transistor T4 may include a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 may be turned on by the bias scan signal of the bias scan line GBL to connect the third node N3 to the third driving voltage line VIL. Accordingly, when the fifth transistor T5 is turned on, the third driving voltage VINT of the third driving voltage line VIL may be applied to the first electrode of the light emitting element LE. The fifth transistor T5 may include a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 may be turned on by the second emission control signal of the second emission control line EL2 to connect the source electrode of the first transistor T1 to the second driving voltage line VDL. Accordingly, when the sixth transistor T6 is turned on, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be disposed between the first node N1 and the drain electrode of the second transistor T2. The first capacitor CP1 may include one electrode connected to the drain electrode of the second transistor T2 and the other electrode connected to the first node N1.

The second capacitor CP2 may be disposed between the gate electrode of the first transistor T1 and the second driving voltage line VDL. The second capacitor CP2 may include one electrode connected to the gate electrode of the first transistor T1 and the other electrode connected to the second driving voltage line VDL.

The first node N1 may be a junction between the gate electrode of the first transistor T1, the drain electrode of the third transistor T3, the other electrode of the first capacitor CP1, and the one electrode of the second capacitor CP2. The second node N2 may be a junction between the drain electrode of the first transistor T1, the source electrode of the third transistor T3, and the source electrode of the fourth transistor T4. The third node N3 may be a junction between the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). In an embodiment, for example, each of the first to sixth transistors T1 to T6 may be a P-type MOSFET, but the embodiment of the specification is not limited thereto. In another embodiment, each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although FIG. 3 illustrates an embodiment where a sub-pixel includes the first sub-pixel SP1 includes six transistors T1 to T6 and two capacitors C1 and C2, the equivalent circuit diagram of the first sub-pixel SP1 is not limited to that shown in FIG. 3. In another embodiment, for example, the number of the transistors and the number of the capacitors of the first sub-pixel SP1 may be changed in various ways.

In an embodiment, the equivalent circuit diagram of the second sub-pixel SP2 of each pixel and the equivalent circuit diagram of the third sub-pixel SP3 of each pixel may be substantially the same as the equivalent circuit diagram of the first sub-pixel SP1 of each pixel described above with reference to FIG. 3. Therefore, any repetitive detailed description of the equivalent circuit diagram of the second sub-pixel SP2 and the equivalent circuit diagram of the third sub-pixel SP3 will be omitted.

FIG. 4 is a plan view illustrating an example of a display panel according to an embodiment.

Referring to FIG. 4, the display area DAA of the display panel 100 according to an embodiment may include the plurality of pixels PX arranged in a matrix form. The non-display area NDA of the display panel 100 according to an embodiment may include the scan driver 610, the emission driver 620, the data driver 700, a first distribution circuit 710, a second distribution circuit 720, the first pad portion PDA1, and a second pad portion PDA2. In an embodiment, no pixel may be disposed or included in the non-display area NDA.

The scan driver 610 may be disposed on the first side of the display area DAA, and the emission driver 620 may be disposed on the second side of the display area DAA. In an embodiment, for example, the scan driver 610 may be disposed on the other side of the display area DAA in the first direction DR1, and the emission driver 620 may be disposed on one side of the display area DAA in the first direction DR1. That is, the scan driver 610 may be disposed on the left side of the display area DAA, and the emission driver 620 may be disposed on the right side of the display area DAA. However, the embodiment of the disclosure is not limited thereto, and in another embodiment, for example, each of the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. In an embodiment, for example, the first pad portion PDA1 may be disposed on the other side of the display area DAA in the second direction DR2. That is, the first pad portion PDA1 may be disposed on the lower side of the display area DAA.

The first pad portion PDA1 may be disposed outside the data driver 700 in the second direction DR2. That is, the first pad portion PDA1 may be disposed closer to the edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board including or made of a rigid material or a flexible printed circuit board including or made of a flexible material.

The first distribution circuit 710 may distribute data voltages applied through the first pad portion PDA1 to the plurality of data lines DL. In an embodiment, for example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. In an embodiment, for example, the first distribution circuit 710 may be disposed on the other side of the display area DAA in the second direction DR2. That is, the first distribution circuit 710 may be disposed on the lower side of the display area DAA.

The second distribution circuit 720 may distribute signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. In an embodiment, for example, the second distribution circuit 720 may be disposed on one side of the display area DAA in the second direction DR2. That is, the second distribution circuit 720 may be disposed on the upper side of the display area DAA.

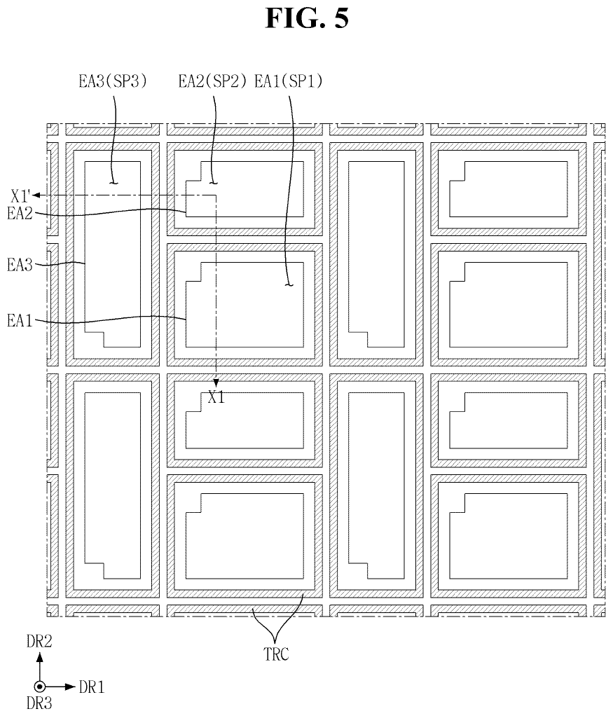

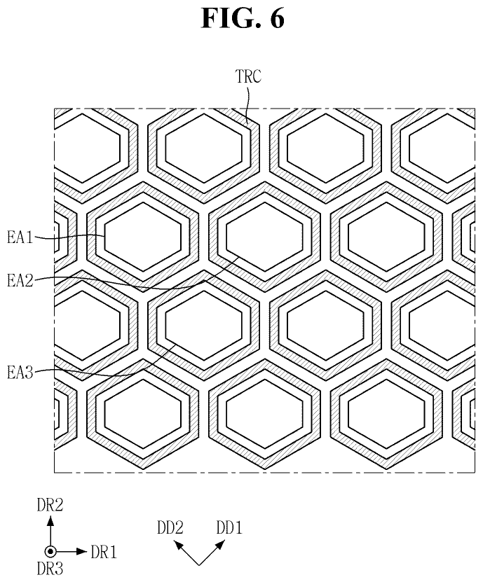

FIGS. 5 and 6 are plan views illustrating embodiments of the display area of FIG. 4.

Referring to FIGS. 5 and 6, in an embodiment, each of the pixels PX may include the first emission area EA1 that is an emission area of the first sub-pixel SP1, the second emission area EA2 that is an emission area of the second sub-pixel SP2, and the third emission area EA3 that is an emission area of the third sub-pixel SP3.

In some embodiments, as shown in FIGS. 5 and 6, the first emission area EA1, the second emission area EA2, and the third emission area EA3 may have, in a plan view (or when viewed in the third direction DR3), a hexagonal shape formed of six straight lines, but the embodiment of the disclosure is not limited thereto. The first emission area EA1, the second emission area EA2, and the third emission area EA3 may have a polygonal shape other than a hexagon, a circular shape, an elliptical shape, or an atypical shape in a plan view.

In some embodiments, as shown in FIG. 5, the maximum length of the third emission area EA3 in the first direction DR1 may be smaller than the maximum length of the first emission area EA1 in the first direction DR1 and the maximum length of the second emission area EA2 in the first direction DR1. The maximum length of the first emission area EA1 in the first direction DR1 and the maximum length of the second emission area EA2 in the first direction DR1 may be substantially the same.

In some embodiments, as shown in FIG. 5, the maximum length of the third emission area EA3 in the second direction DR2 may be greater than the maximum length of the first emission area EA1 in the second direction DR2 and the maximum length of the second emission area EA2 in the second direction DR2. The maximum length of the first emission area EA1 in the second direction DR2 may be greater than the maximum length of the second emission area EA2 in the second direction DR2.

In an embodiment, as shown in FIG. 5, the first emission area EA1 and the second emission area EA2 in each of the plurality of pixels PX may be adjacent to each other in the second direction DR2. The first emission area EA1 and the third emission area EA3 may be adjacent to each other in the first direction DR1. The second emission area EA2 and the third emission area EA3 may be adjacent to each other in the first direction DR1. The area of the first emission area EA1, the area of the second emission area EA2, and the area of the third emission area EA3 may be different.

In another embodiment, as shown in FIG. 6, in each of the plurality of pixels PX, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2.

In the illustrated drawing, the first diagonal direction DD1 intersects each of the first direction DR1 and the second direction DR2 as horizontal directions. For example, the first diagonal direction DD1 may be a direction inclined by 45 degrees with respect to the first direction DR1 and the second direction DR2, but the disclosure is not limited thereto. The second diagonal direction DD2 intersects each of the first direction DR1 and the second direction DR2 as horizontal directions. For example, the second diagonal direction DD1 may be a direction inclined by 45 degrees with respect to the opposite direction of the first direction DR1 and the second direction DR2, but the disclosure is not limited thereto. The second diagonal direction DD2 is a direction perpendicular to the first diagonal direction DD1.

The first emission area EA1 may emit light of a first color, the second emission area EA2 may emit light of a second color, and the third emission area EA3 may emit light of a third color. Here, the light of the first color may be light of a red wavelength band, the light of the second color may be light of a green wavelength band, and the light of the third color may be light of a blue wavelength band. For example, the blue wavelength band is a wavelength band of light whose main peak wavelength is in a range of about 370 nanometers (nm) to about 460 nm, the green wavelength band is a wavelength band of light whose main peak wavelength is in a range of about 480 nm to about 560 nm, and the red wavelength band is a wavelength band of light whose main peak wavelength is in a range of about 600 nm to about 750 nm.

FIGS. 5 and 6 illustrate embodiments where each of the plurality of pixels PX includes three emission areas EA1, EA2, and EA3, but the embodiment of the disclosure is not limited thereto. In another embodiment, for example, each of the plurality of pixels PX may include four or more emission areas.

In addition, the shape and disposition of the emission areas of the plurality of pixels PX are not limited to those illustrated in FIGS. 5 and 6. In an embodiment, for example, the emission areas of the plurality of pixels PX may be disposed in a stripe structure in which the emission areas are arranged in the first direction DR1, a PenTile® structure in which the emission areas are arranged in a diamond shape, or a hexagonal structure in which the emission areas having, in a plan view, a hexagonal shape are arranged side by side as shown in FIG. 6.

FIG. 7 is a cross-sectional view illustrating an example of a display panel taken along line X1-X1′ of FIG. 5.

Referring to FIG. 7, an embodiment of the display panel 100 may include a semiconductor backplane SBP, a light emitting element backplane EBP, a display element layer EML, an encapsulation layer TFE, an optical layer OPL, a cover layer CVL, and a polarizing plate POL.

The semiconductor backplane SBP may include the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 (see FIG. 4) described with reference to FIG. 4.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the aforementioned first type impurity. In an embodiment, for example, where the first type impurity is a p-type impurity, the second type impurity may be an n-type impurity. Alternatively, when the first type impurity is an n-type impurity, the second type impurity may be a p-type impurity.

Each of the plurality of well regions WA may include a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the pixel transistors PTR increases, such that punch-through and hot carrier phenomena that might be caused by a short channel are effectively prevented.

A first semiconductor insulating film SINS1 may be disposed on the semiconductor substrate SSUB. The first semiconductor insulating film SINS1 may include or be formed of silicon carbonitride (SiCN) or a silicon oxide (SiOx)-based inorganic film, but the embodiment of the disclosure is not limited thereto.

A second semiconductor insulating film SINS2 may be disposed on the first semiconductor insulating film SINS1. The second semiconductor insulating film SINS2 may include or be formed of a silicon oxide (SiOx)-based inorganic film, but the embodiment of the disclosure is not limited thereto.

The plurality of contact terminals CTE may be disposed on the second semiconductor insulating film SINS2. Each of the plurality of contact terminals CTE may be connected to at least one selected from the gate electrode GE, the source region SA, and the drain region DA of each of the pixel transistors PTR through holes defined or formed through the first semiconductor insulating film SINS1 and the second semiconductor insulating film SINS2. The plurality of contact terminals CTE may include or be formed of at least one selected from copper (Cu), aluminum (Al), tungsten (W), molybdenum (Mo), chromium (Cr), gold (Au), titanium (Ti), nickel (Ni), and neodymium (Nd), or a combination or alloy thereof.

A third semiconductor insulating film SINS3 may be disposed on a side surface of each of the plurality of contact terminals CTE. The top surface of each of the plurality of contact terminals CTE may be exposed without being covered by the third semiconductor insulating film SINS3. The third semiconductor insulating film SINS3 may include or be formed of a silicon oxide (SiOx)-based inorganic film, but the embodiment of the disclosure is not limited thereto.

In another embodiment, the semiconductor substrate SSUB may be replaced with a glass substrate or a polymer resin substrate such as polyimide. In such an embodiment, thin film transistors may be disposed on the glass substrate or the polymer resin substrate. The glass substrate may be a rigid substrate that does not bend, and the polymer resin substrate may be a flexible substrate that can be bent or curved.

The light emitting element backplane EBP may include a plurality of conductive layers ML1 to ML8, a plurality of vias VA1 to VA9, and a plurality of insulating films INS1 to INS9.

The first to eighth conductive layers ML1 to ML8 serve to connect the plurality of contact terminals CTE exposed from the semiconductor backplane SBP to thereby implement the pixel circuit of the first sub-pixel SP1 shown in FIG. 4. In an embodiment, for example, the first to sixth transistors T1 to T6 are merely disposed on the semiconductor backplane SBP, and the connection line of the first to sixth transistors T1 to T6 and the first capacitor C1 and the second capacitor C2 may be disposed in the first to eighth conductive layers ML1 to ML8. In addition, a connection portion between the drain region corresponding to the drain electrode of the fourth transistor T4, the source region corresponding to the source electrode of the fifth transistor T5, and the first electrode of the light emitting element LE may also be disposed in the first to eighth conductive layers ML1 to ML8.

The first insulating film INS1 may be disposed on the semiconductor backplane SBP. Each of the first vias VA1 may penetrate (or extend through) the first insulating film INS1 to be connected to the contact terminal CTE exposed from the semiconductor backplane SBP. Each of the first conductive layers ML1 may be disposed on the first insulating film INS1 and may be connected to the first via VA1.

The second insulating film INS2 may be disposed on the first insulating film INS1 and the first conductive layers ML1. Each of the second vias VA2 may penetrate(or extend through) the second insulating film INS2 and be connected to the exposed first conductive layer ML1. Each of the second conductive layers ML2 may be disposed on the second insulating film INS2 and may be connected to the second via VA2.

The third insulating film INS3 may be disposed on the second insulating film INS2 and the second conductive layers ML2. Each of the third vias VA3 may penetrate (or extend through) the third insulating film INS3 and be connected to the exposed second conductive layer ML2. Each of the third conductive layers ML3 may be disposed on the third insulating film INS3 and may be connected to the third via VA3.

A fourth insulating film INS4 may be disposed on the third insulating film INS3 and the third conductive layers ML3. Each of the fourth vias VA4 may penetrate (or extend through) the fourth insulating film INS4 and be connected to the exposed third conductive layer ML3. Each of the fourth conductive layers ML4 may be disposed on the fourth insulating film INS4 and may be connected to the fourth via VA4.

A fifth insulating film INS5 may be disposed on the fourth insulating film INS4 and the fourth conductive layers ML4. Each of the fifth vias VA5 may penetrate (or extend through) the fifth insulating film INS5 and be connected to the exposed fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layers ML5. Each of the sixth vias VA6 may penetrate (or extend through) the sixth insulating film INS6 and be connected to the exposed fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layers ML6. Each of the seventh vias VA7 may penetrate (or extend through) the seventh insulating film INS7 and be connected to the exposed sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layers ML7. Each of the eighth vias VA8 may penetrate (or extend through) the eighth insulating film INS8 and be connected to the exposed seventh conductive layer ML7. Each of the eighth conductive layers ML8 may be disposed on the eighth insulating film INS8 and may be connected to the eighth via VA8.

The first to eighth conductive layers ML1 to ML8 and the first to eighth vias VA1 to VA8 may include or be formed of substantially a same material as each other. The first to eighth conductive layers ML1 to ML8 and the first to eighth vias VA1 to VA8 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination or alloy thereof. First to eighth insulating films INS1 to INS8 may include or be formed of a silicon oxide (SiOx)-based inorganic film, but the embodiment of the disclosure is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be larger than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be larger than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. In an embodiment, for example, the thickness of the first conductive layer ML1 is about 1360 angstrom (Å); the thickness of each of the second conductive layer ML2, the third conductive layer ML3, the fourth conductive layer ML4, the fifth conductive layer ML5, and the sixth conductive layer ML6 is about 1440 Å; and the thickness of each of the first via VA1, the second via VA2, the third via VA3, the fourth via VA4, the fifth via VA5, and the sixth via VA6 is about 1150 Å. However, the thicknesses of the first to sixth conductive layers ML1, ML2, ML3, ML4, ML5, and ML6 and the first to sixth vias VA1, VA2, VA3, VA4, VA5, and VA6 are not limited thereto.

The thickness of each of the seventh conductive layer ML7 and the eighth conductive layer ML8 may be larger than the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. The thickness of the seventh conductive layer ML7 and the thickness of the eighth conductive layer ML8 may be larger than the thickness of the seventh via VA7 and the thickness of the eighth via VA8, respectively. The thickness of each of the seventh via VA7 and the eighth via VA8 may be larger than the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same. In an embodiment, for example, the thickness of each of the seventh conductive layer ML7 and the eighth conductive layer ML8 is about 9000 Å, and the thickness of each of the seventh via VA7 and the eighth via VA8 is about 6000 Å. However, the thicknesses of the seventh conductive layer ML7, the eighth conductive layer ML8, the seventh via VA7, and the eighth via VA8 are not limited thereto.

A ninth insulating film INS9 may be disposed on the eighth insulating film INS8 and the eighth conductive layer ML8. The ninth insulating film INS9 may include or be formed of a silicon oxide (SiOx)-based inorganic film, but the embodiment of the disclosure is not limited thereto.

Each of the ninth vias VA9 may penetrate the ninth insulating film INS9 and be connected to the exposed eighth conductive layer ML8. The ninth vias VA9 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination or alloy thereof. The thickness of the ninth via VA9 is about 16500 Å. However, the thickness of the ninth via VA9 is not limited thereto.

The display element layer EML may be disposed on the light emitting element backplane EBP. The display element layer EML may include light emitting elements LE each including a reflective electrode layer RL, tenth and eleventh insulating films INS10 and INS11, a tenth via VA10, a first electrode AND, a light emitting stack ES, and a second electrode CAT; a pixel defining film PDL; and a plurality of trenches TRC.

The reflective electrode layer RL may be disposed on the ninth insulating film INS9. The reflective electrode layer RL may include at least one reflective electrode RL1, RL2, RL3, and RL4. In an embodiment, for example, the reflective electrode layer RL may include first to fourth reflective electrodes RL1, RL2, RL3, and RL4 as shown in FIG. 7, but is not limited thereto.

Each of the first reflective electrodes RL1 may be disposed on the ninth insulating film INS9, and may be connected to the ninth via VA9. The first reflective electrodes RL1 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination or alloy thereof. In an embodiment, for example, the first reflective electrodes RL1 may include titanium nitride (TiN).

Each of the second reflective electrodes RL2 may be disposed on the first reflective electrode RL1. The second reflective electrodes RL2 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination or alloy thereof. In an embodiment, for example, the second reflective electrodes RL2 may include aluminum (Al).

Each of the third reflective electrodes RL3 may be disposed on the second reflective electrode RL2. The third reflective electrodes RL3 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination or a combination or alloy thereof. In an embodiment, for example, the third reflective electrodes RL3 may include titanium nitride (TiN).

The fourth reflective electrodes RL4 may be respectively disposed on the third reflective electrodes RL3. The fourth reflective electrodes RL4 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination or alloy thereof. In an embodiment, for example, the fourth reflective electrodes RL4 may include titanium (Ti).

In such an embodiment, since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4. In an embodiment, for example, the thickness of each of the first reflective electrode RL1, the third reflective electrode RL3, and the fourth reflective electrode RL4 is about 100 Å, and the thickness of the second reflective electrode RL2 is about 850 Å. However, the thicknesses of the first to fourth reflective electrodes RL1, RL2, RL3, and RL4 are not limited thereto.

The tenth insulating film INS10 may be disposed on the ninth insulating film INS9. The tenth insulating film INS10 may be disposed in a space between the reflective electrode layers RL adjacent to each other in a horizontal direction. The tenth insulating film INS10 may include or be formed of a silicon oxide (SiOx)-based inorganic film, but the embodiment of the disclosure is not limited thereto. In some embodiments, although not shown in the drawing, the tenth insulating film INS10 may be disposed not only between the reflective electrode layers RL but also on the reflective electrode layer RL.

The eleventh insulating film INS11 may be disposed on the tenth insulating film INS10 and the reflective electrode layer RL. The eleventh insulating film INS11 may include or be formed of a silicon oxide (SiOx)-based inorganic film, but the embodiment of the disclosure is not limited thereto. The tenth insulating film INS10 and the eleventh insulating film INS11 may be an optical auxiliary layer through which light reflected by the reflective electrode layer RL passes, among light emitted from the light emitting elements LE.

In some embodiments, in at least any one sub-pixel among the first sub-pixel SP1, the second sub-pixel SP2, and the third sub-pixel SP3, the total thickness of the insulating film disposed between the first electrode AND and the reflective electrode layer RL may be different in the first sub-pixel SP1, the second sub-pixel SP2, and the third sub-pixel SP3 to adjust the resonance distance of light emitted from the light emitting elements LE.

In an embodiment, as shown in the drawing, where the tenth insulating film INS10 is not disposed between the first electrode AND and the reflective electrode layer RL but the eleventh insulating film INS11 is disposed therebetween, the thickness of the eleventh insulating film INS11 disposed in each of the first sub-pixel SP1, the second sub-pixel SP2, and the third sub-pixel SP3 may be different from each other. In an embodiment, for example, the thickness of the eleventh insulating film INS11 disposed in the first sub-pixel SP1 may be smaller than the thickness of the eleventh insulating film INS11 disposed in the second sub-pixel SP2, and the thickness of the eleventh insulating film INS11 disposed in the second sub-pixel SP2 may be smaller than the thickness of the eleventh insulating film INS11 disposed in the third sub-pixel SP3.

In another embodiment, in the first sub-pixel SP1, neither the tenth insulating film INS10 nor the eleventh insulating film INS11 may be disposed between the first electrode AND and the reflective electrode layer RL, and in the sub-pixel SP2, at least one selected from the tenth insulating film INS10 and the eleventh insulating film INS11 may be disposed between the first electrode AND and the reflective electrode layer RL, and in the third sub-pixel SP3, both the tenth insulating film INS10 and the eleventh insulating film INS11 may be disposed between the first electrode AND and the reflective electrode layer RL.

In another embodiment, a twelfth insulating film (not shown) may be further disposed between the first electrode AND and the reflective electrode layer RL. In such an embodiment, in the first sub-pixel SP1, at least one selected from the tenth insulating film INS10, the eleventh insulating film INS11, and the twelfth insulating film may be disposed between the first electrode AND and the reflective electrode layer RL, in the second sub-pixel SP2, any two of the tenth insulating film INS10, the eleventh insulating film INS11, and the twelfth insulating film may be disposed between the first electrode AND and the reflective electrode layer RL, and in the third sub-pixel SP3, all the tenth insulating film INS10, the eleventh insulating film INS11, and the twelfth insulating film may be disposed between the first electrode AND and the reflective electrode layer RL.

In such an embodiment, the distance between the first electrode AND and the reflective electrode layer RL may be different in the first sub-pixel SP1, the second sub-pixel SP2, and the third sub-pixel SP3. That is, the second sub-pixel SP2, and the third sub-pixel SP3, the presence/absence or thickness of the tenth insulating film INS10 and the eleventh insulating film INS11 may be set in each of the first sub-pixel SP1, the second sub-pixel SP2, and the third sub-pixel SP3 to adjust the distance from the reflective electrode layer RL to the second electrode CAT according to the main wavelength of the light emitted from each of the first sub-pixel SP1.

In an embodiment, as shown in FIG. 3, the total thickness of the insulating film disposed between the first electrode AND and the reflective electrode layer RL may increase in the order of the first sub-pixel SP1, the second sub-pixel SP2, and the third sub-pixel SP3, the disclosure is not limited thereto. In such an embodiment, the distance between the first electrode AND and the reflective electrode layer RL in the third sub-pixel SP3 is larger than the distance between the first electrode AND and the reflective electrode layer RL in the second sub-pixel SP2 and the distance between the first electrode AND and the reflective electrode layer RL in the first sub-pixel SP1, and the distance between the first electrode AND and the reflective electrode layer RL in the second sub-pixel SP2 is larger than the distance between the first electrode AND and the reflective electrode layer RL in the first sub-pixel SP1, but the embodiments of the disclosure is not limited thereto. The size relationship of the total thickness of the insulating film disposed between the first electrode AND and the reflective electrode layer RL in each of the first sub-pixel SP1, the second sub-pixel SP2, and the third sub-pixel SP3 may be variously changed depending on the resonance distance.

Each of the tenth vias VA10 may be connected to the reflective electrode layer RL exposed through the tenth insulating film INS10 and/or the eleventh insulating film INS11. The tenth vias VA10 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination or alloy thereof. The thickness of the tenth via VA10 in the second sub-pixel SP2 may be smaller than the thickness of the tenth via VA10 in the third sub-pixel SP3, and the thickness of the tenth via VA10 in the first sub-pixel SP1 may be smaller than the thickness of the tenth via VA10 in the second sub-pixel SP2, but the disclosure is not limited thereto.

The first electrode AND of each of the light emitting elements LE may be disposed on the eleventh interlayer insulating film INS11 and connected to the tenth via VA10. The first electrode AND of each of the light emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light emitting elements LE may include or be formed of at least one selected from copper (Cu), aluminum (Al), tungsten (W), molybdenum (Mo), chromium (Cr), gold (Au), titanium (Ti), nickel (Ni), and neodymium (Nd), or a combination or alloy thereof. In an embodiment, for example, the first electrode AND of each of the light emitting elements LE may be titanium nitride (TiN).

The pixel defining film PDL may be disposed on a part of the first electrode AND of each of the light emitting elements LE. The pixel defining film PDL may cover the edge of the first electrode AND of each of the light emitting elements LE. The pixel defining film PDL may serve to partition the first emission areas EA1, the second emission areas EA2, and the third emission areas EA3.

The first emission area EA1 may be defined as an area in which the first electrode AND, the light emitting stack ES, and the second electrode CAT are sequentially stacked in the first sub-pixel SP1 to emit light. The second emission area EA2 may be defined as an area in which the first electrode AND, the light emitting stack ES, and the second electrode CAT are sequentially stacked in the second sub-pixel SP2 to emit light. The third emission area EA3 may be defined as an area in which the first electrode AND, the light emitting stack ES, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may include or be formed of a silicon oxide (SiOx)-based inorganic layer, but the embodiment of the disclosure is not limited thereto. The first pixel defining film PDL1, the second pixel defining film PDL2, and the third pixel defining film PDL3 may each have a thickness of about 500 Å.

In such an embodiment where the first pixel defining film PDL1, the second pixel defining film PDL2, and the third pixel defining film PDL3 are formed as one pixel defining film, the height of the one pixel defining film increases, such that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, to effectively prevent the first encapsulation inorganic film TFE1 from being cut off due to the step coverage, the first pixel defining film PDL1, the second pixel defining film PDL2, and the third pixel defining film PDL3 may have a cross-sectional structure having a stepped portion. In an embodiment, for example, the width of the first pixel defining film PDL1 may be greater than the width of the second pixel defining film PDL2 and the width of the third pixel defining film PDL3, and the width of the second pixel defining film PDL2 may be greater than the width of the third pixel defining film PDL3. Each of the width of the first pixel defining film PDL1, the width of the second pixel defining film PDL2, and the width of the third pixel defining film PDL3 refers to the length in the horizontal direction perpendicular to the third direction DR3.

Each of the plurality of trenches TRC may penetrate the first pixel defining film PDL1, the second pixel defining film PDL2, and the third pixel defining film PDL3. Furthermore, each of the plurality of trenches TRC may be defined or formed through the eleventh insulating film INS11. The eleventh insulating film INS11 may be partially recessed at each of the plurality of trenches TRC.

At least one trench TRC may be disposed between adjacent sub-pixels SP1, SP2, and SP3. Although FIG. 7 illustrates an embodiment where two trenches TRC are disposed between adjacent sub-pixels SP1, SP2, and SP3, the embodiment of the disclosure is not limited thereto.

The light emitting stack ES may include a plurality of intermediate layers. FIG. 7 illustrates an embodiment where the light emitting stack ES has a three-tandem structure including a first stack layer IL1, a second stack layer IL2, and a third stack layer IL3, but the embodiment of the disclosure is not limited thereto. In another embodiment, for example, the light emitting stack ES may have a two-tandem structure including two intermediate layers.

In the three-tandem structure, the light emitting stack ES may have a tandem structure including a plurality of stack layers IL1, IL2, and IL3 that emit different lights, respectively. In an embodiment, for example, the light emitting stack ES may include the first stack layer IL1 that emits light of the first color, the second stack layer IL2 that emits light of the third color, and the third stack layer IL3 that emits light of the second color. The first stack layer IL1, the second stack layer IL2, and the third stack layer IL3 may be sequentially stacked one on another.

The first stack layer IL1 may have a structure in which a first hole transport layer, a first organic light emitting layer that emits light of the first color, and a first electron transport layer are sequentially stacked one on another. The second stack layer IL2 may have a structure in which a second hole transport layer, a second organic light emitting layer that emits light of the third color, and a second electron transport layer are sequentially stacked one on another. The third stack layer IL3 may have a structure in which a third hole transport layer, a third organic light emitting layer that emits light of the second color, and a third electron transport layer are sequentially stacked one on another.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and may be disposed on the bottom surface of each trench TRC. Due to the trench TRC, the first stack layer IL1 may be cut off between adjacent sub-pixels SP1, SP2, and SP3. The second stack layer IL2 may be disposed on the first stack layer IL1. Due to the trench TRC, the second stack layer IL2 may be cut off between adjacent sub-pixels SP1, SP2, and SP3. A cavity ESS or an empty space may be disposed between the first stack layer IL1 and the second stack layer IL2. The third stack layer IL3 may be disposed on the second stack layer IL2. The third stack layer IL3 is not cut off by the trench TRC and may be disposed to cover the second stack layer IL2 in each of the trenches TRC. That is, in the three-tandem structure, each of the plurality of trenches TRC may be a structure for cutting off the first and second stack layers IL1 and IL2, the first charge generation layer, and the second charge generation layer of the display element layer EML between the sub-pixels SP1, SP2, and SP3 adjacent to each other. In addition, in the two-tandem structure, each of the trenches TRC may be a structure for cutting off the charge generation layer disposed between a lower intermediate layer and an upper intermediate layer, and the lower intermediate layer.

In an embodiment, the height of each of the plurality of trenches TRC may be greater than the height of the pixel defining film PDL to stably cut off the first and second stack layers IL1 and IL2 of the display element layer EML between adjacent sub-pixels SP1, SP2, and SP3. The height of each of the plurality of trenches TRC refers to the length of each of the plurality of trenches TRC in the third direction DR3. The height of the pixel defining film PDL refers to the length of the pixel defining film PDL in the third direction DR3. In an embodiment, another structure configured to cut off the first to third stack layers IL1, IL2, and IL3 of the display element layer EML between the neighboring sub-pixels SP1, SP2, and SP3 may exist or be provided instead of the trench TRC. In an embodiment, for example, instead of the trench TRC, a reverse tapered partition wall may be disposed on the pixel defining film PDL.

The number of the stack layers IL1, IL2, and IL3 that emit different lights is not limited to that shown in FIG. 7. In an embodiment, for example, the light emitting stack ES may include two intermediate layers. In such an embodiment, one of the two intermediate layers may be substantially the same as the first stack layer IL1, and the other may include a second hole transport layer, a second organic light emitting layer, a third organic light emitting layer, and a second electron transport layer. In such an embodiment, a charge generation layer for supplying electrons to one intermediate layer and supplying charges to the other intermediate layer may be disposed between the two intermediate layers.

In addition, FIG. 7 illustrates an embodiment where the first to third stack layers IL1, IL2, and IL3 are all disposed in the first emission area EA1, the second emission area EA2, and the third emission area EA3, but the embodiment of the disclosure is not limited thereto. In another embodiment, for example, the first stack layer IL1 may be disposed in the first emission area EA1, and may not be disposed in the second emission area EA2 and the third emission area EA3. In such an embodiment, the second stack layer IL2 may be disposed in the second emission area EA2 and may not be disposed in the first emission area EA1 and the third emission area EA3. In such an embodiment, the third stack layer IL3 may be disposed in the third emission area EA3 and may not be disposed in the first emission area EA1 and the second emission area EA2. In such an embodiment, first to third color filters CF1, CF2, and CF3 of the optical layer OPL may be omitted.

The second electrode CAT may be disposed on the third stack layer IL3. The second electrode CAT may be disposed on the third stack layer IL3 in each of the plurality of trenches TRC. The second electrode CAT may include or be formed of a transparent conductive material (TCO) such as ITO or IZO that can transmit light or a semi-transmissive conductive material such as magnesium (Mg), silver (Ag), or an alloy of Mg and Ag. In an embodiment where the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE2 to effectively prevent oxygen or moisture from permeating into the display element layer EML. In an embodiment, for example, the encapsulation layer TFE may include the first encapsulation inorganic film TFE1, and a second encapsulation inorganic film TFE2.

The first encapsulation inorganic film TFE1 may be disposed on the second electrode CAT. The first encapsulation inorganic film TFE1 may be formed as a multilayer in which one or more inorganic films, each including at least one selected from silicon nitride (SiNx), silicon oxy nitride (SiON), and silicon oxide (SiOx), are alternately stacked. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may include or be formed of titanium oxide (TiOx) or aluminum oxide (AlOx), but the embodiment of the disclosure is not limited thereto. The second encapsulation inorganic film TFE2 may be formed by an atomic layer deposition (ALD) process. The thickness of the second encapsulation inorganic film TFE2 may be smaller than the thickness of the first encapsulation inorganic film TFE1.

The display panel 100 may further include an organic film APL. An organic film APL may be a layer for increasing the interfacial adhesion between the encapsulation layer TFE and the optical layer OPL. The organic film APL may be an organic film such as acrylic resin, epoxy resin, phenolic resin, polyamide resin, or polyimide resin.

The optical layer OPL may include a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the organic layer APL.

The first color filter CF1 may overlap the first emission area EA1 of the first sub-pixel SP1. The first color filter CF1 may transmit light of the first color, i.e., light of a red wavelength band. The red wavelength band refers to a wavelength band of about 600 nm to about 750 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, i.e., light of a green wavelength band. The green wavelength band refers to a wavelength band of about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, i.e., light of a blue wavelength band. The blue wavelength band refers to a wavelength band of about 370 nm to about 460 nm. Thus, the third color filter CF3 may transmit light of the third color among light emitted from the third emission area EA3.

The plurality of lenses LNS may be disposed on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction.

The filling layer FIL may be disposed on the plurality of lenses LNS. The filling layer FIL may have a predetermined refractive index such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be disposed on the filling layer FIL. The cover layer CVL may be a glass substrate or a polymer resin. In an embodiment where the cover layer CVL is a glass substrate, the cover layer CVL may be attached onto the filling layer FIL. In such an embodiment, the filling layer FIL serves to bond the cover layer CVL. In an embodiment where the cover layer CVL is a glass substrate, the cover layer CVL serves as an encapsulation substrate. In an embodiment where the cover layer CVL is a polymer resin, the cover layer CVL may be directly applied onto the filling layer FIL.

The polarizing plate POL may be disposed on one surface of the cover layer CVL. The polarizing plate POL may be a structure for preventing visibility degradation caused by reflection of external light. The polarizing plate POL may include a linear polarizing plate and a phase retardation film. In an embodiment, for example, the phase retardation film may be λ/4 plate (quarter-wave plate), but the embodiment of the disclosure is not limited thereto. However, when visibility degradation caused by reflection of external light is sufficiently overcome by the first to third color filters CF1, CF2, and CF3, the polarizing plate POL may be omitted.

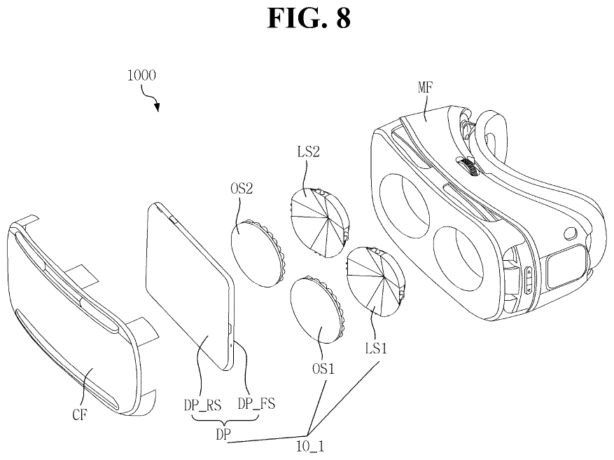

FIG. 8 is an exploded perspective view illustrating a head mounted display according to an embodiment.

Referring to FIG. 8, an embodiment of a head mounted display 1000 is formed in the form of glasses or a head mount to provide an image to a user using a display device 10_1.

The head mounted display 1000 may include a see-through type that provides augmented reality based on actual external objects and a see-closed type that provides virtual reality to the user on a screen independent from the external objects.

The head mounted display 1000 may include a main frame MF mounted on the user's body, the display device 10_1 mounted on the main frame MF to display an image, and a cover frame CF that covers the display device 10_1.

The display device 101 may be integrally provided in the head mounted display 1000 that may be carried by the user and easily attached to or detached from a face or a head, and may be formed to be assembled to the head mounted display 1000. The display device 10_1 may be substantially the same as the display device 10 described in conjunction with FIGS. 1 and 2.

The display device 101 may include a display panel DP that displays an image, first and second lens frames OS1 and OS2 that refract an image display light, and first and second multi-channel lenses LS1 and LS2 that form an optical path so that the image display light of the display panel DP is visible to the user.

The main frame MF may be worn on the user's face and head. The main frame MF may be formed in a shape corresponding to the user's head and facial structure.

The main frame MF may be integrally provided in display device 10_1, that is, the display panel DP, the first and second lens frames OS1 and OS2, and the first and second multi-channel lenses LS1 and LS2. Alternatively, the display panel DP, the first and second lens frames OS1 and OS2, and the first and second multi-channel lenses LS1 and LS2 may be assembled and mounted to the main frame MF. In such an embodiment, the main frame MF may have a space or a structure for accommodating the display panel DP, the first and second lens frames OS1 and OS2, and the first and second multi-channel lenses LS1 and LS2. The main frame MF may further include a structure such as a strap or a band to facilitate the mounting, and a controller, an image processing unit, and a lens accommodating unit may be further included in the main frame MF.

The display panel DP may be divided into a front surface DP_FS where an image is displayed, and a rear surface DP_RS located on the opposite side of the front surface DP_FS. Image display light may be emitted from the front surface DP_FS of the display panel DP. As will be described later, the first and second lens frames OS1 and OS2 may be disposed on the front surface DP_FS of the display panel DP, and the first and second multi-channel lenses LS1 and LS2 may be disposed on the front surfaces of the first and second lens frames OS1 and OS2. In an embodiment, although not shown, at least one infrared camera may be disposed on at least one of the front surface DP_FS or the rear surface DP_RS of the display panel DP. The display panel DP may be substantially the same as the display panel 100 described in conjunction with FIG. 1 and the like.

The display panel DP may be built in the main frame MF in a state where the first and second lens frames OS1 and OS2 and the first and second multi-channel lenses LS1 and LS2 are mounted and fixed, or may be detachably assembled to the main frame MF. The display panel DP may be opaque, transparent, or translucent depending on the design of the display device 10_1, for example, the usage type of the display device 10_1.

Each of the first and second lens frames OS1 and OS2 may have an area corresponding to the image display surface of the display panel DP, and may be formed in a shape corresponding to that of the image display surface. Further, the first and second lens frames OS1 and OS2 may be formed to have an area and a shape corresponding to those of the rear surfaces of the first and second multi-channel lenses LS1 and LS2, respectively. The rear surfaces of the first and second lens frames OS1 and OS2 may be attached to the image display surface of the display panel DP, and the first and second multi-channel lenses LS1 and LS2 may be attached to the front surfaces of the first and second lens frames OS1 and OS2, respectively. The first and second lens frames OS1 and OS2 refract the image display light emitted from the image display surface of the display panel DP at a preset angle and provide it to the first and second multi-channel lenses LS1 and LS2 disposed on the front surfaces thereof, respectively.

In an embodiment, the first and second lens frames OS1 and OS2 may refract the image display light, which is emitted from the image display surface of the display panel DP toward the front side, toward an outer side (or toward an outer peripheral side) compared to the front side and provide the refracted image display light to the first and second multi-channel lenses LS1 and LS2 disposed on the front surfaces thereof, respectively. In particular, the first and second lens frames OS1 and OS2 may refract the image display light incident on the rear surfaces thereof toward the outer side (or toward the outer peripheral side) and provide the refracted image display light to the rear surfaces of the first and second multi-channel lenses LS1 and LS2, respectively.

The first and second multi-channel lenses LS1 and LS2 may form a path for light emitted through the first and second lens frames OS1 and OS2, such that the image display light is visible to the user's eyes on the front side.

The first and second multi-channel lenses LS1 and LS2 may provide a plurality of channels (or paths) through which the image display light emitted from the display panel DP passes. The plurality of channels may provide the image display light emitted from the display panel DP to the user through different paths. The image display light emitted through the first and second lens frames OS1 and OS2 may be incident on the respective channels, and the image magnified through the respective channels may be focused on the user's eyes.

The first and second multi-channel lenses LS1 and LS2 may be respectively arranged on the front surfaces the first and second lens frames OS1 and OS2 to correspond to the positions of the user's left eye and right eye. The first and second multi-channel lenses LS1 and LS2 may be accommodated in the main frame MF.

The first and second multi-channel lenses LS1 and LS2 may refract and/or reflect the image display light emitted through the first and second lens frames OS1 and OS2 at least once to form a path to the user's eyes. At least one infrared light source may be further disposed at the main frame MF, or on one side of each of the first and second multi-channel lenses LS1 and LS2 facing the user's eyes.

The cover frame CF may be disposed on the rear surface DP_RS of the display panel DP to cover the display panel DP and may protect the display panel DP. The cover frame CF may be attached to the main frame MF while covering the display panel DP.

In an embodiment, the display device 101 may further include a controller (not shown) for controlling the overall operation of the display device 10_1 including the display panel DP. The controller may control the image display operation of the display panel DP and audio devices. In such an embodiment, the controller performs image processing (e.g., image mapping) according to the magnification ratio and the image display path corresponding to the first and second lens frames OS1 and OS2 and the first and second multi-channel lenses LS1 and LS2, and controls the mapped image to be displayed on the display panel DP. The controller may be implemented as a dedicated processor including an embedded processor and/or a general-purpose processor including a central processing unit or an application processor, but is not limited thereto.

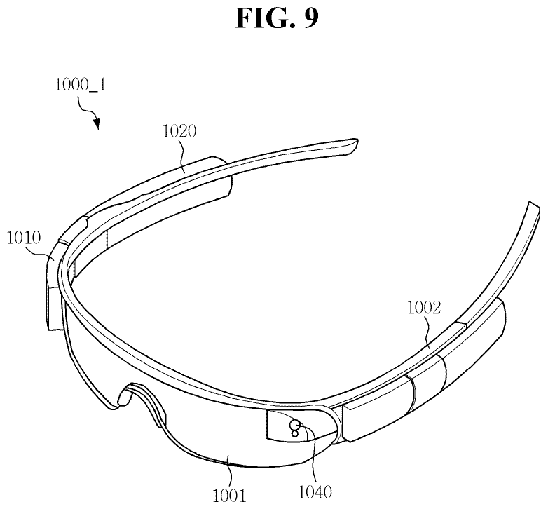

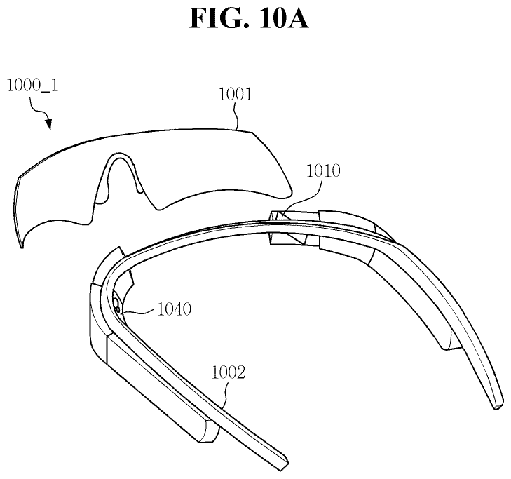

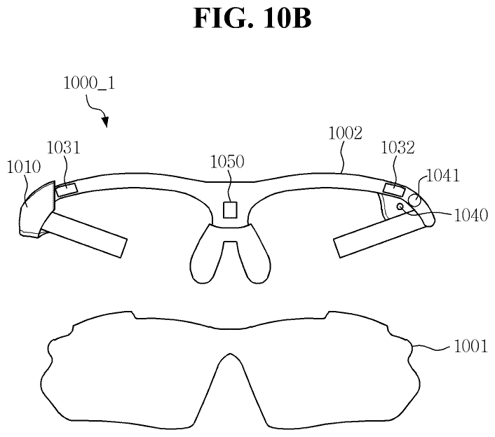

FIG. 9 is a perspective view showing an augmented reality content providing device according to an embodiment. FIG. 10A is a rear exploded perspective view of the augmented reality content providing device of FIG. 9. FIG. 10B is a front exploded perspective view of the augmented reality content providing device of FIG. 9.

Referring to FIGS. 9, 10A, and 10B, an embodiment of an augmented reality content providing device 10001 may include a support frame 1002 supporting at least one transparent lens 1001, at least one image display module 1010, a surrounding environment detector 1040, and a control module 1020.

The support frame 1002 may be formed in the form of glasses including a spectacle frame supporting the edge of at least one transparent lens 1001 and spectacle frame legs. The shape of the support frame 1002 is not limited to a glasses type, and may be formed in a goggle type including the transparent lens 1001, or a head mount type.

The transparent lens 1001 may include left and right parts formed integrally with each other, or first and second transparent lenses formed separately from each other. The transparent lens 1001, which includes the integrated left and right parts or the separated first and second transparent lenses, may include or be made of glass or plastic that is transparent or translucent. Accordingly, the user may view the image of reality through the transparent lens 1001 that includes the integrated right and left parts or the separated first and second transparent lenses. Here, the transparent lens 1001, that is, the integrated lens or the first and second transparent lenses, may have a refractive power in consideration of the user's eyesight.

The transparent lens 1001 may further include at least one reflective member that reflects the augmented reality content image provided from the at least one image display module 1010 toward the transparent lens 1001 or the user's eyes, and optical members that adjust a focus and a size. One or more reflective member may be built in the transparent lens 1001 to be integrated with the transparent lens 1001, and may be formed as a plurality of refractive lenses or a plurality of prisms with a predetermined curvature.

The at least one image display module 1010 may include a micro LED display device (micro-LED), a nano LED display device (nano-LED), an organic light emitting display device (OLED), an inorganic light emitting display device (inorganic EL), a quantum dot light emitting display device (QED), a cathode ray display (CRT), a liquid crystal display (LCD), or the like. The image display module 1010 may substantially include the display device 10 described with reference to FIGS. 1 and 2.

The surrounding environment detector 1040 is assembled or integrally formed with the support frame 1002, and detects the distance (or depth) to an object on the front side of the support frame 1002, the illuminance, the moving direction of the support frame 1002, the moving distance, the tilt, or the like. To this end, the surrounding environment detector 1040 includes a depth sensor 1041 such as an infrared sensor or a LiDAR sensor, and an image sensor 1050 such as a camera. Further, the surrounding environment detector 1040 may further include at least one motion sensor among an illumination sensor, a human body detection sensor, a gyro sensor, a tilt sensor, and an acceleration sensor. Further, the surrounding environment detector 1040 may further include first and second biometric sensors 1031 and 1032 for detecting movement information of the user's eyes or pupils.

The surrounding environment detector 1040 may transmit sensing signals generated by the depth sensor 1041 and at least one motion sensor to the control module 1020 in real time. Further, the image sensor 1050 may transmit image data in units of at least one frame generated in real time to the control module 1020. The first and second biometric sensors 1031 and 1032 of the surrounding environment detector 1040 may transmit the detected pupil detection signals to the control module 1020.

The control module 1020 may be assembled to at least one side of the support frame 1002 together with the at least one image display module 1010 or may be formed integrally with the support frame 1002. The control module 1020 supplies augmented reality content data to the at least one image display module 1010 so that the at least one image display module 1010 displays an augmented reality content, e.g., an augmented reality content image. At the same time, the control module 1020 may receive sensing signals, image data, and pupil detection signals from the surrounding environment detector 1040 in real time.

Hereinafter, an apparatus for manufacturing the display devices 10, 10_1, 10_2, and 10_3 according to embodiment will be described.

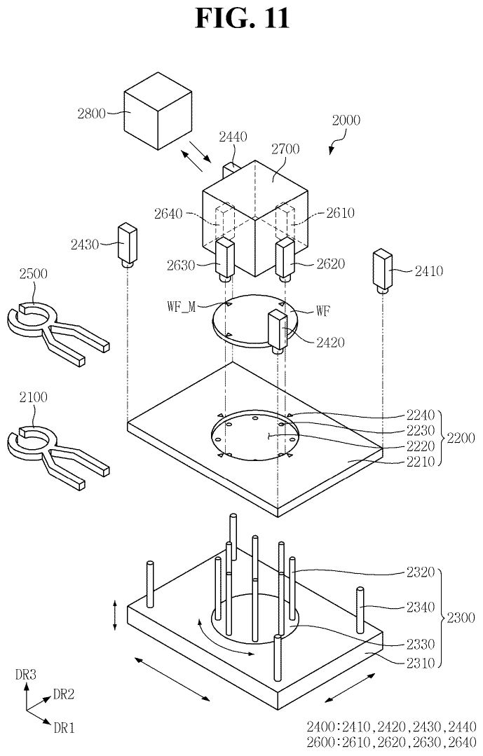

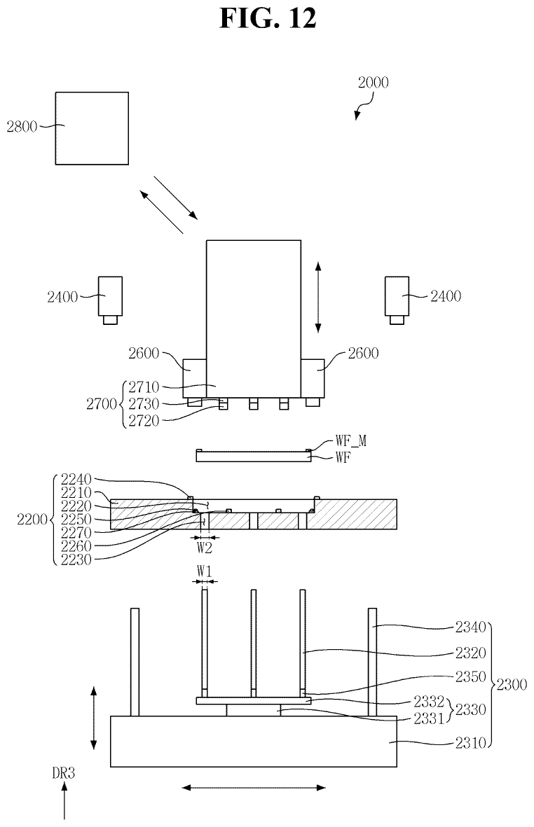

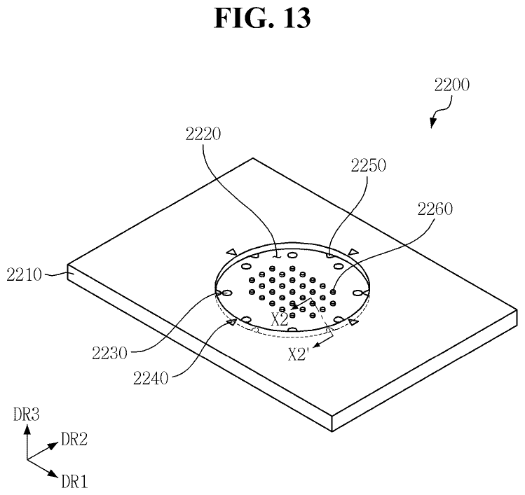

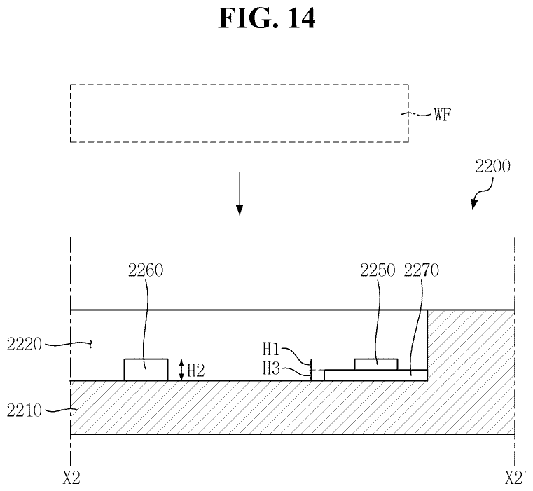

FIG. 11 is a perspective view showing an apparatus for manufacturing a display device according to an embodiment. FIG. 12 is a cross-sectional view showing an apparatus for manufacturing a display device according to an embodiment. FIG. 13 is a perspective view showing a carrier according to an embodiment. FIG. 14 is a cross-sectional view showing the carrier taken along line X2-X2′ of FIG. 13.

Referring to FIGS. 11 to 14 in addition to FIG. 7, an embodiment of a display device manufacturing apparatus 2000 may be an apparatus that couples a wafer WF and a carrier 2200. The wafer WF may be the semiconductor substrate SSUB of the display devices 10, 101, 10_2, and 10_3 according to the above-described embodiment. The carrier 2200 is a transport device for mounting and transporting the wafer WF in the manufacturing process of the display devices 10, 10_1, 10_2, and 10_3 according to an embodiment.

Unlike a conventional display process for performing a micro-scale patterning process, in embodiments of the manufacturing process of the display devices 10, 10_1, 10_2, and 10_3, a finer patterning process and a semiconductor process capable of performing cell integration may be performed to achieve high resolution. In an embodiment where the semiconductor process is performed, the semiconductor process equipment is used instead of a conventional display process equipment. However, in order to reduce costs, the conventional display process equipment may be used in logistics/transport equipment for moving or storing a target wafer WF between the respective semiconductor processes. In addition, in order to reduce costs, the conventional display process equipment may be used in processes in which the conventional display process equipment is allowed to be used in addition to the semiconductor process for achieving high resolution.

The shape and size of a conventional mother substrate using a polymer resin substrate such as polyimide or a glass substrate are different from those of the wafer WF included in the display devices 10, 10_1, 10_2, and 10_3 according to the above-described embodiment. Therefore, in order to use the conventional display process equipment, the display device manufacturing apparatus 2000 according to an embodiment may couple the wafer WF to the carrier 2200 having a same shape and size as those of a conventional mother substrate. The wafer WF coupled to the carrier 2200 may correspond to an object in the conventional display process equipment.

The display device manufacturing apparatus 2000 according to an embodiment may include a carrier transfer unit 2100, a carrier 2200, an alignment unit 2300, a first vision device 2400, a wafer transfer unit 2500, a second vision device 2600, a pressing unit 2700, and a controller 2800.

The carrier transfer unit 2100 carries and transfers the carrier 2200. The carrier transfer unit 2100 may adjust the position of the carrier 2200 on the alignment unit 2300. The carrier transfer unit 2100 may mount the carrier 2200 on the alignment unit 2300.

The carrier 2200 is a transport device for mounting and transferring the wafer WF. As described above, the carrier 2200 may have a same shape and size as those of a mother substrate used in a conventional display process. In an embodiment, for example, the carrier 2200 may have a quadrilateral shape in a plan view, but is not limited thereto.

In some embodiments, the carrier 2200 may have the same dimensions as those of a 10.5^{th} generation mother substrate, which are 2940 millimeters (mm) in width and 3370 mm in height, the same dimensions as those of an eight generation mother substrate, which are 2200 mm in width and 2500 mm in height, the same dimensions as those of a seventh generation mother substrate, which are 1870 mm in width and 2200 mm in height, the same dimensions as those of a sixth generation mother substrate, which are 1500 mm in width and 1850 mm in height, the same dimensions as those of a 5.5^{th} generation mother substrate, which are 1300 mm in width and 1500 mm in height, the same dimensions as those of a fourth generation mother substrate, which are 730 mm in width and 920 mm in height, the same dimensions as those of a third generation mother substrate, which are 550 mm in width and 650 mm in height, the same dimensions as those of a second generation mother substrate, which are 370 mm in width and 470 mm in height, or the same dimensions as those of a first generation mother substrate, which are 270 mm in width and 360 mm in height. However, the size of the carrier 2200 is not limited thereto.

The carrier 2200 may include a carrier body 2210, a wafer accommodating portion 2220, a pin hole 2230, a carrier mark 2240, a coupling portion 2250, a buffer portion 2260, and a step compensation portion 2270.

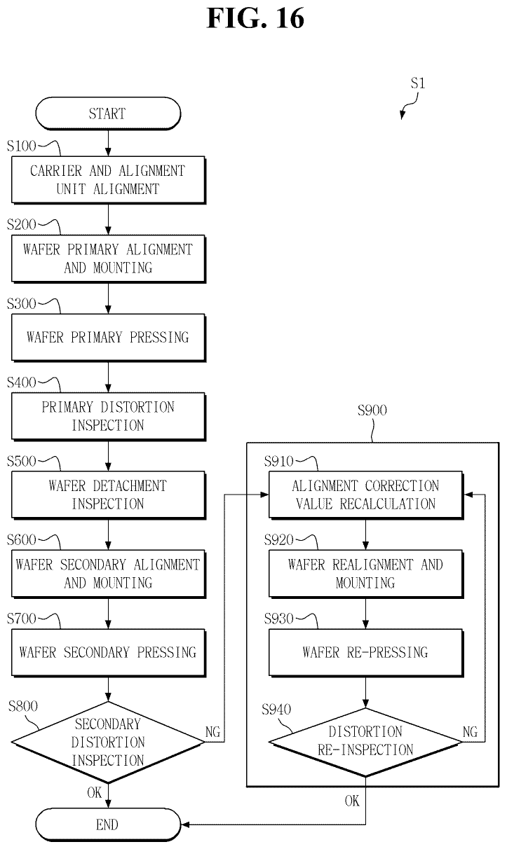

The carrier body 2210 constitutes the overall shape of the carrier 2200. The carrier body 2210 may support the wafer WF. The carrier body 2210 may be mounted on the alignment unit 2300 in a display device manufacturing method S1 (see FIG. 16). The carrier body 2210 may be mounted on a manufacturing process equipment in the manufacturing process of the display devices 10, 10_1, 10_2, and 10_3 according to the above-described embodiment.

The wafer accommodating portion 2220 may be provided on the carrier body 2210. In an embodiment, for example, the wafer accommodating portion 2220 may be a groove recessed from the top surface to the bottom surface of the carrier body 2210. The wafer accommodating portion 2220 provides a space in which the wafer WF may be accommodated. The shape of the wafer accommodating portion 2220 may correspond to the shape of the wafer WF. The size of the wafer accommodating portion 2220 may be larger than or equal to the size of the wafer WF.

The pin hole 2230 may be defined or formed in the carrier body 2210. In an embodiment, for example, the pin hole 2230 may be a hole extending from the bottom surface of the wafer accommodating portion 2220 to the bottom surface of the carrier body 2210 in the third direction DR3. At least one pin hole 2230 may be disposed in the carrier body 2210, and preferably a plurality of pin holes may be provided. The pin hole 2230 may be a passage through which a pin 2320 of the alignment unit 2300 may reciprocate in the third direction DR3.

The carrier mark 2240 may be located on the carrier body 2210. In an embodiment, for example, the carrier mark 2240 may be located on the top surface of the carrier body 2210. The carrier mark 2240 may be disposed outside the wafer accommodating portion 2220. At least one carrier mark 2240 may be disposed on the carrier body 2210, e.g., a plurality of carrier marks may be provided. In an embodiment, as shown in FIG. 11, four carrier marks 2240 may be provided, but the disclosure is not limited thereto, and the shape of the carrier mark 2240 is also not limited to that shown in the drawing.

The carrier mark 2240 is an alignment mark for aligning the wafer WF and the carrier 2200. In an embodiment, for example, the wafer WF may include a wafer mark WF_M. At least one wafer mark WF_M may be disposed on the wafer WF, and preferably a plurality of wafer marks may be provided. In an embodiment, for example, the number of wafer marks WF_M may be the same as the number of carrier marks 2240, but the disclosure is not limited thereto. Whether or not the carrier 2200 and the wafer WF are properly aligned with each other may be determined by the relative positions of the carrier mark 2240 and the wafer mark WF_M.

The coupling portion 2250 may be disposed in the wafer accommodating portion 2220, as shown in FIGS. 13 and 14. The coupling portion 2250 may be disposed on the bottom surface of the wafer accommodating portion 2220. The coupling portion 2250 may be located between the wafer WF and the bottom surface of the wafer accommodating portion 2220 when the wafer WF and the carrier 2200 are coupled. The coupling portion 2250 is a coupling device for coupling the wafer WF and the carrier 2200 to each other.

In an embodiment, the coupling portion 2250 may include an adhesive material or a tackifying material. In an embodiment, for example, the coupling portion 2250 may include a physical sticky chuck.

In another embodiment, the coupling portion 2250 may be involved in coupling and detachment between the wafer WF and the carrier 2200 using an electrostatic force. In an embodiment, for example, the coupling portion 2250 may include an electrostatic chuck. In some embodiments, when the coupling portion 2250 includes an electrostatic chuck, the display device manufacturing apparatus 2000 may further include a separate electrostatic force supply unit capable of supplying an electrostatic force to the electrostatic chuck and wires that connect the electrostatic force supply unit to the electrostatic chuck.

The buffer portion 2260 may be disposed in the wafer accommodating portion 2220, as shown in FIGS. 13 and 14. The buffer portion 2260 may be disposed on the bottom surface of the wafer accommodating portion 2220. The buffer portion 2260 may be disposed on a portion of the bottom surface of the wafer accommodating portion 2220 other than the portion where the coupling portion 2250 is disposed. The buffer portion 2260 may be located between the wafer WF and the bottom surface of the wafer accommodating portion 2220 when the wafer WF and the carrier 2200 are coupled. In some embodiments, the buffer portion 2260 may be located closer to a center of the wafer accommodating portion 2220 than the coupling portion 2250 in a plan view. That is, the coupling portion 2250 may be located closer to the outside of the wafer accommodating portion 2220 than the buffer portion 2260 in a plan view. The buffer portion 2260 reduces the amount of impact applied to the wafer WF when the wafer WF and the carrier 2200 are coupled. In an embodiment, for example, the buffer portion 2260 may include an embossing material.

In some embodiments, the buffer portion 2260 may be an island-type structure, as shown in FIG. 13. Accordingly, the amount of impact is distributed when the wafer WF and the carrier 2200 are coupled, and air bubbles are effectively prevented from being accumulated at the central portion.

The step compensation portion 2270 may be disposed in the wafer accommodating portion 2220, as shown in FIG. 14. The step compensation portion 2270 may be disposed on the bottom surface of the wafer accommodating portion 2220. The step compensation portion 2270 may be disposed between the coupling portion 2250 and the bottom surface of the wafer accommodating portion 2220.

The step compensation portion 2270 is a device for compensating for the height difference between the coupling portion 2250 and the buffer portion 2260. For example, in some embodiments, a thickness H2 of the buffer portion 2260 may be greater than a thickness H1 of the coupling portion 2250. In this case, the step compensation portion 2270 may be disposed below the coupling portion 2250. The thickness H2 of the buffer portion 2260 may be substantially equal to the sum of the thickness H1 of the coupling portion 2250 and a thickness H3 of the step compensation portion 2270.

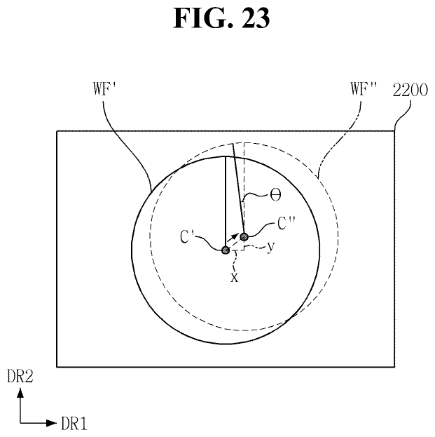

The alignment unit 2300 is an alignment device for aligning the carrier 2200 and the wafer WF. The alignment unit 2300 may be disposed below the carrier 2200. The alignment unit 2300 may adjust the position (e.g., x of FIG. 23) in the first direction DR1, the position (e.g., y of FIG. 23) in the second direction DR2, the position in the third direction DR3 of the wafer WF, and the rotation angle (e.g., θ of FIG. 23) of the wafer WF. In an embodiment, for example, the alignment unit 2300 may be a UVW (three phase) stage.

The alignment unit 2300 may include a base 2310, the pin 2320, a pin driver 2330, a carrier fixing part 2340, and a first pressure sensor 2350.

The base 2310 provides a space where other components of the alignment unit 2300, such as the pin 2320, the pin driver 2330, the carrier fixing part 2340, and the first pressure sensor 2350, may be disposed. The base 2310 may support the other components of the alignment unit 2300. Although FIG. 11 illustrate an embodiment where the base 2310 has a quadrilateral shape, the disclosure is not limited thereto.

The pin 2320 may be disposed on the base 2310. The pin 2320 may be disposed between the base 2310 and the carrier 2200. The pin 2320 may have a shape extending in the third direction DR3. The pin 2320 may be a pillar extending from the top surface of the base 2310 in the third direction DR3. At least one pin 2320 may be disposed on the base 2310, e.g., a plurality of pins may be provided. The number of pins 2320 may be substantially the same as the number of pin holes 2230. The pin 2320 may pass through the pin hole 2230 to support the wafer WF. The pin 2320 may mount the wafer WF in the wafer accommodating portion 2220 of the carrier 2200 while moving in the opposite direction of the third direction DR3 by the pin driver 2330. Alternatively, the pin 2320 may detach the wafer WF coupled to the carrier 2200 from the carrier 2200 while moving in the third direction DR3 by the pin driver 2330.

In some embodiments, as shown in FIG. 12, a width W2 of the pin hole 2230 may be greater than or equal to a width W1 of the pin 2320. Although FIG. 11 illustrates an embodiment where the pin 2320 has a cylindrical shape, the disclosure is not limited thereto.

The pin driver 2330 may be disposed on the base 2310. The pin driver 2330 may be disposed between the pin 2320 and the base 2310 in the third direction DR3. The pin driver 2330 may be a driving device for adjusting the position of the pin 2320. In some embodiments, the pin driver 2330 may include a vertical driver 2331 and a rotational driver 2332.

The vertical driver 2331 may move the pin 2320 in the third direction DR3. In an embodiment, for example, the vertical driver 2331 may be stretched or contracted in the third direction DR3 to move the pin 2320 in the third direction DR3. Accordingly, the wafer WF mounted on the pin 2320 may move in the third direction DR3. The rotational driver 2332 may adjust the rotation angle of the pin 2320. Accordingly, the rotation angle of the wafer WF mounted on the pin 2320 may be adjusted.

The carrier fixing part 2340 may be disposed on the base 2310. The carrier fixing part 2340 may be disposed between the base 2310 and the carrier 2200. In some embodiments, as shown in the drawing, the carrier fixing part 2340 may have a shape extending in the third direction DR3. The carrier fixing part 2340 may be a pillar extending from the top surface of the base 2310 in the third direction DR3. However, the disclosure is not limited thereto, and the carrier fixing part 2340 may have various shapes capable of supporting the carrier 2200 between the base 2310 and the carrier 2200.

In some embodiments, at least one carrier fixing part 2340 may be disposed on the base 2310, and preferably a plurality of carrier fixing parts may be provided. In an embodiment, for example, as shown in the drawing, four carrier fixing parts 2340 may be disposed adjacent to the corners of the base 2310. However, the disclosure is not limited thereto, and the carrier fixing part 2340 may be one wall surrounding the pin 2320 and disposed along the outer edge of the base 2310. The number and shape of the carrier fixing parts 2340 are not limited to those shown in the drawing.

The carrier fixing part 2340 may support the carrier 2200. The carrier 2200 may be mounted on the carrier fixing part 2340. The carrier fixing part 2340 may fix the carrier 2200 when the carrier 2200 and the wafer WF are coupled to each other.

The first pressure sensor 2350 may be disposed between the base 2310 and the pin 2320 in the third direction DR3. In an embodiment, for example, the first pressure sensor 2350 may be disposed between the pin driver 2330 and the pin 2320 in the third direction DR3. The first pressure sensor 2350 may be disposed below the pin 2320. In some embodiments, the first pressure sensor 2350 may be disposed for each pin 2320 in a one-to-one correspondence. The first pressure sensor 2350 may measure the pressing force applied to each pin 2320 when the wafer WF is detached in a wafer detachment inspection process (process S500) (see FIG. 16).

In an embodiment, the alignment unit 2300 may further include a base driver (not shown). The base driver may be a driving device for adjusting the positions of the base 2310 and other components disposed on the base 2310. In an embodiment, for example, the base driver may move the base 2310 and other components disposed on the base 2310 in the first direction DR1, the second direction DR2, and the third direction DR3. When the base driver moves the base 2310 in the first direction DR1 and the second direction DR2, the wafer WF may move in the first direction DR1 and the second direction DR2 along the pin 2320. When the base driver moves the base 2310 in the third direction DR3, the carrier fixing part 2340 may move in the third direction DR3 to mount the carrier 2200.

In an embodiment, the alignment unit 2300 may further include a case (not shown) that may be blocked from an external space and accommodate other components of the alignment unit 2300, such as the base 2310, the pin 2320, the pin driver 2330, the carrier fixing part 2340, and the first pressure sensor 2350. The case may be disposed on the side surface of the alignment unit 2300 to surround the base 2310, the pin 2320, the pin driver 2330, the carrier fixing part 2340, and the first pressure sensor 2350.

The first vision device 2400 may be disposed on the carrier 2200 and the alignment unit 2300. The first vision device 2400 may capture images of the carrier 2200 and the alignment unit 2300. The first vision device 2400 provides the captured images of the carrier 2200 and the alignment unit 2300 to the controller 2800.

In some embodiments, the first vision device 2400 may include first to fourth cameras 2410, 2420, 2430, and 2440. The first to fourth cameras 2410, 2420, 2430, and 2440 may be disposed on the corners of the carrier 2200 and the corners of the alignment unit 2300. The first to fourth cameras 2410, 2420, 2430, and 2440 may capture images of the corners of the carrier 2200 and the corners of the alignment unit 2300, and the controller 2800 may determine whether or not the corners of the carrier 2200 and the corners of the alignment unit 2300 are properly aligned with each other. However, the number of cameras included in the first vision device 2400 is not limited thereto, and may be variously changed. In an embodiment, for example, the number of cameras included in the first vision device 2400 may be equal to the number of corners of the carrier 2200.

The wafer transfer unit 2500 carries and transfers the wafer WF. The wafer transfer unit 2500 may adjust the position of the wafer WF on the carrier 2200 and the alignment unit 2300. The wafer transfer unit 2500 may mount the wafer WF on the pin 2320 of the alignment unit 2300.

The second vision device 2600 may be disposed on the carrier 2200 and the wafer WF. In some embodiments, the second vision device 2600 may be disposed on the sidewall of the pressing unit 2700, but the disclosure is not limited thereto. The second vision device 2600 may capture images of the carrier 2200 and the wafer WF. The second vision device 2600 provides the captured images of the carrier 2200 and the wafer WF to the controller 2800.

In some embodiments, the second vision device 2600 may include fifth to eighth cameras 2610, 2620, 2630, and 2640. The fifth to eighth cameras 2610, 2620, 2630, and 2640 may be disposed on the outer edge (or sidewall) of the wafer accommodating portion 2220. The fifth to eighth cameras 2610, 2620, 2630, and 2640 may capture images of the carrier mark 2240 of the carrier 2200 and the wafer mark WF_M of the wafer WF, and the controller 2800 may determine whether or not the carrier mark 2240 and the wafer mark WF_M of the wafer WF are properly aligned with each other. However, the number of cameras included in the second vision device 2600 is not limited thereto, and may be variously changed. In an embodiment, for example, the number of cameras included in the second vision device 2600 may be equal to the number of carrier marks 2240.

The pressing unit 2700 may be disposed on the carrier 2200 and the wafer WF. The pressing unit 2700 provides a pressing force to the wafer WF mounted on the carrier 2200. The wafer WF may be coupled to the carrier 2200 by the pressing force of the pressing unit 2700.

In some embodiments, the pressing unit 2700 may include a pressing part body 2710, a pressing part 2720, and a second pressure sensor 2730.

The pressing part body 2710 constitutes the overall shape of the pressing unit 2700. The pressing part body 2710 provides a space where the pressing part 2720 and the second pressure sensor 2730 are disposed. Although FIGS. 11 and 12 illustrate an embodiment where the pressing part body 2710 has a rectangular parallelepiped shape, the shape of the pressing part body 2710 is not limited thereto.

The pressing part 2720 may be disposed on the pressing part body 2710. In an embodiment, for example, the pressing part 2720 may be disposed on the bottom surface of the pressing part body 2710. The pressing part 2720 may be disposed between the pressing part body 2710 and the carrier 2200 or between the pressing part body 2710 and the wafer WF. The pressing part 2720 may be in direct contact with the wafer WF when the wafer WF is pressed. The pressing part 2720 may include an elastic material to minimize damage to the wafer WF. The plurality of pressing parts 2720 may be provided to distribute the pressing force applied to the wafer WF. In such an embodiment, the pressing parts 2720 of an island-type structure may be evenly distributed on the bottom surface of the pressing part body 2710. Although three pressing parts 2720 are illustrated in FIG. 12 for convenience of illustration, the number of pressing parts 2720 is not limited thereto.

The second pressure sensor 2730 may be disposed between the pressing part body 2710 and the pressing part 2720. In an embodiment, for example, the second pressure sensor 2730 may be disposed between the pressing part body 2710 and the pressing part 2720 in the third direction DR3. The second pressure sensor 2730 may be disposed above the pressing part 2720. In some embodiments, the second pressure sensor 2730 may be disposed for each pressing part 2720 in a one-to-one correspondence. The second pressure sensor 2730 may measure the pressing force applied to each pressing part 2720 when the wafer WF is pressed in a wafer primary pressing process (process S300) (see FIG. 16), a wafer secondary pressing process (process S700) (see FIG. 16), and a wafer re-pressing process (process S930) (see FIG. 16).

In an embodiment, the pressing unit 2700 may further include a pressing driver (not shown). The pressing driver may be a driving device for adjusting the position of the pressing unit 2700. In an embodiment, for example, the pressing driver may move the pressing unit 2700 in the third direction DR3. When the pressing driver moves the pressing unit 2700 in the third direction DR3, the pressing part 2720 may press the wafer WF to couple the wafer WF and the carrier 2200.

The controller 2800 may perform an operation for controlling other components of the display device manufacturing apparatus 2000, and generate a processing signal and provide it to the other components. In an embodiment, for example, the controller 2800 may determine whether or not the carrier 2200 and the alignment unit 2300 are aligned and control the carrier transfer unit 2100, the alignment unit 2300, and the first vision device 2400 to align the carrier 2200 and the alignment unit 2300. In another embodiment, for example, the controller 2800 may determine whether or not the carrier 2200 and the wafer WF are aligned and control the alignment unit 2300, the wafer transfer unit 2500, and the second vision device 2600 to align the carrier 2200 and the wafer WF. In another embodiment, for example, the controller 2800 may control the pressing unit 2700 to control the pressing force when the wafer WF and the carrier 2200 are coupled. In another embodiment, for example, the controller 2800 may control the alignment unit 2300 to control the pressing force when the wafer WF is detached.

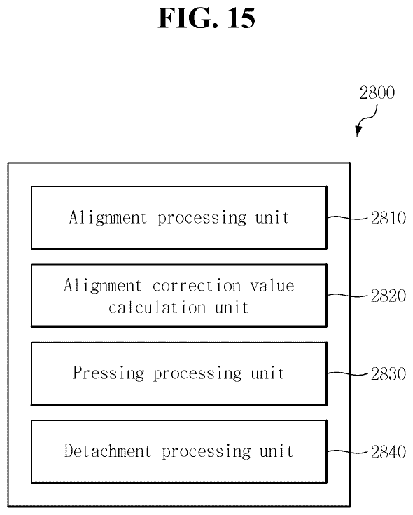

Hereinafter, the controller 2800 will be described with further reference to FIG. 15.

FIG. 15 is a block diagram showing a controller according to an embodiment.

Referring to FIG. 15 in addition to FIGS. 11 to 14, an embodiment of the controller 2800 may include an alignment processing unit 2810, an alignment correction value calculation unit 2820, a pressing processing unit 2830, and a detachment processing unit 2840.

The alignment processing unit 2810 may control the alignment between the carrier 2200 and the alignment unit 2300 and the alignment between the carrier 2200 and the wafer WE.

In an embodiment, for example, the alignment processing unit 2810 may provide a driving signal to the carrier transfer unit 2100 to locate the carrier 2200 on the alignment unit 2300. The alignment processing unit 2810 may provide a driving signal to the first vision device 2400 to capture images of the carrier 2200 and the alignment unit 2300. The alignment processing unit 2810 may determine whether or not the carrier 2200 and the alignment unit 2300 are properly aligned with each other based on the images captured by the first vision device 2400. When the carrier 2200 and the alignment unit 2300 are properly or correctly aligned, the alignment processing unit 2810 may provide a driving signal to the alignment unit 2300 to mount and fix the carrier 2200 on the carrier fixing part 2340 of the alignment unit 2300.

In another embodiment, for example, the alignment processing unit 2810 may provide a driving signal to the wafer transfer unit 2500 to locate the wafer WF on the carrier 2200. The alignment processing unit 2810 may provide a driving signal to the second vision device 2600 to capture images of the carrier mark 2240 of the carrier 2200 and the wafer mark WF_M of the wafer WF. The alignment processing unit 2810 may determine whether or not the carrier 2200 and the wafer WF are properly aligned with each other based on the images captured by the second vision device 2600. When the carrier 2200 and the wafer WF are correctly or properly aligned with each other, the alignment processing unit 2810 may provide a driving signal to the pin driver 2330 of the alignment unit 2300 to mount the wafer WF in the wafer accommodating portion 2220 of the carrier 2200.

The alignment correction value calculation unit 2820 may calculate a degree of distortion of the wafer WF due to pressing. The alignment correction value calculation unit 2820 may calculate a degree of distortion of the wafer WF due to pressing as a correction value and reflect the correction value in advance when the wafer WF is realigned.

In an embodiment, for example, after the wafer WF is pressed, the alignment correction value calculation unit 2820 may provide a driving signal to the second vision device 2600 to capture the images of the carrier mark 2240 of the carrier 2200 and the wafer mark WF_M of the wafer WF again. The alignment correction value calculation unit 2820 may calculate a degree of distortion of the wafer WF based on the images captured by the second vision device 2600 after pressing by comparing the image before pressing with the image after pressing. The alignment correction value calculation unit 2820 may calculate a degree of distortion of the wafer WF after pressing as a correction value and provide the correction value to the alignment unit 2300. The alignment unit 2300 may align the wafer WF and the carrier 2200 by shifting from a previous alignment position by the correction value, and in this state, the secondary pressing of the wafer WF may be performed again.

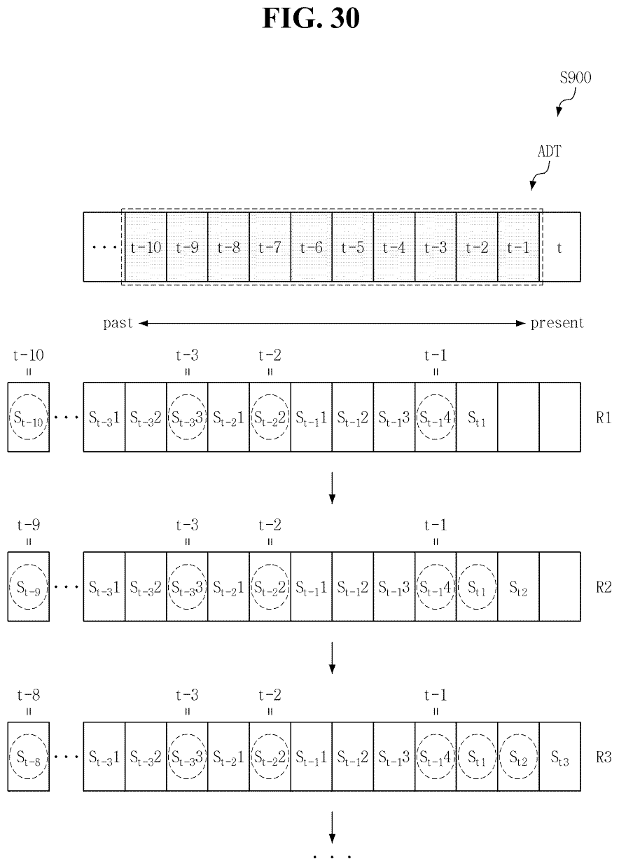

In an embodiment, when the distortion still occurs between the wafer WF and the carrier 2200 even after the secondary pressing, the alignment correction value calculation unit 2820 may calculate a new correction value using accumulated data of previous correction values. This will be described later with reference to FIG. 30.

In the display device manufacturing apparatus 2000 according to an embodiment, the alignment accuracy of the carrier 2200 and the wafer WF may be improved by the calculation of the correction value by the alignment correction value calculation unit 2820.

The pressing processing unit 2830 may control the pressing force of the pressing unit 2700 when the wafer WF is pressed.

In an embodiment, for example, the pressing processing unit 2830 may provide a driving signal to the pressing unit 2700 to cause the pressing part 2720 to press the wafer WF mounted on the carrier 2200. At the same time, the pressing processing unit 2830 may receive the pressing force applied to the pressing part 2720 from the second pressure sensor 2730 of the pressing unit 2700 in real time. Accordingly, the pressing processing unit 2830 may cause the pressing unit 2700 to provide an appropriate pressing force to the wafer WF in real time, thereby effectively preventing damage to the wafer WF.

The detachment processing unit 2840 may control the pressing force of the alignment unit 2300 when the wafer WF is detached.

In an embodiment, for example, the detachment processing unit 2840 may provide a driving signal to the alignment unit 2300 to cause the pin 2320 to press the wafer WF coupled to the carrier 2200. At the same time, the detachment processing unit 2840 may receive the pressing force applied to the pin 2320 from the first pressure sensor 2350 of the alignment unit 2300 in real time. Accordingly, the detachment processing unit 2840 may cause the alignment unit 2300 to provide an appropriate pressing force to the wafer WF in real time, thereby effectively preventing damage to the wafer WF.

Hereinafter, a method of manufacturing a display device according to an embodiment will be described.

FIG. 16 is a flowchart showing a method of manufacturing a display device according to an embodiment.

Referring to FIG. 16, the display device manufacturing method S1 according to an embodiment may include a carrier and alignment unit alignment process (process S100), a wafer primary alignment and mounting process (process S200), a wafer primary pressing process (process S300), a primary distortion inspection process (process S400), a wafer detachment inspection process (process S500), a wafer secondary alignment and mounting process (process S600), a wafer secondary pressing process (process S700), a secondary distortion inspection process (process S800), and an alignment correction value recalculation and wafer realignment process (process S900).

The alignment correction value recalculation and wafer realignment process (process S900) may include an alignment correction value recalculation process (process S910), a wafer realignment and mounting process (process S920), a wafer re-pressing process (process S930), and a distortion re-inspection process (process S940).

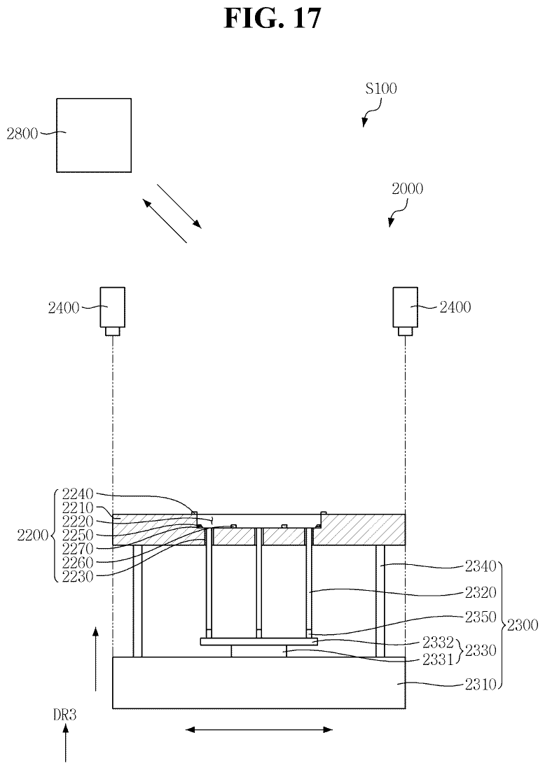

FIG. 17 is a cross-sectional view showing process S100 of FIG. 16.

Referring to FIG. 17 in addition to FIGS. 15 and 16, in the carrier and alignment unit alignment process (process S100), the carrier transfer unit 2100 (see FIG. 11) may receive a driving signal from the alignment processing unit 2810 of the controller 2800 to locate the carrier 2200 on the alignment unit 2300.

The first vision device 2400 may receive a driving signal from the alignment processing unit 2810 of the controller 2800 to capture images of the carrier 2200 and the alignment unit 2300. The first vision device 2400 may provide the captured images to the alignment processing unit 2810 of the controller 2800.

The alignment processing unit 2810 may determine whether or not the carrier 2200 and the alignment unit 2300 are properly aligned with each other based on the images captured by the first vision device 2400 and provided thereto. The alignment processing unit 2810 may provide a driving signal to the carrier transfer unit 2100 (see FIG. 11) in real time to align the carrier 2200 with the alignment unit 2300.

When the carrier 2200 and the alignment unit 2300 are correctly or properly aligned, the alignment unit 2300 may receive a driving signal from the alignment processing unit 2810 and move in the third direction DR3. Accordingly, the carrier 2200 may be mounted and fixed on the carrier fixing part 2340 of the alignment unit 2300.

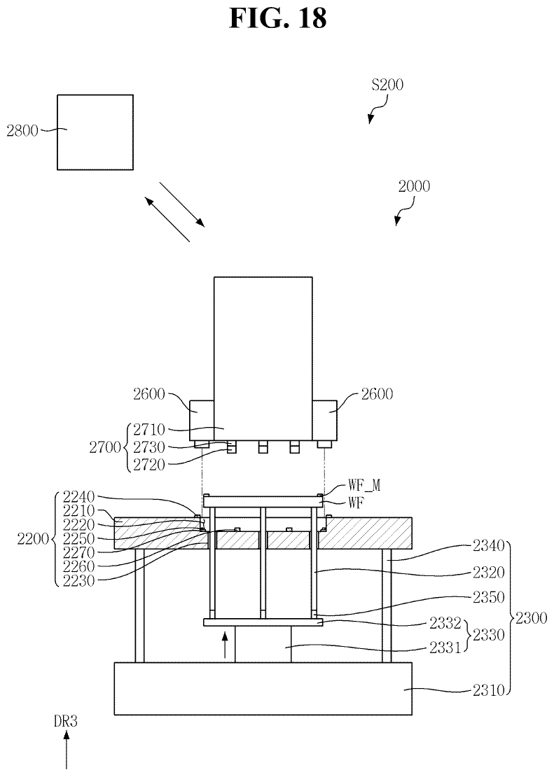

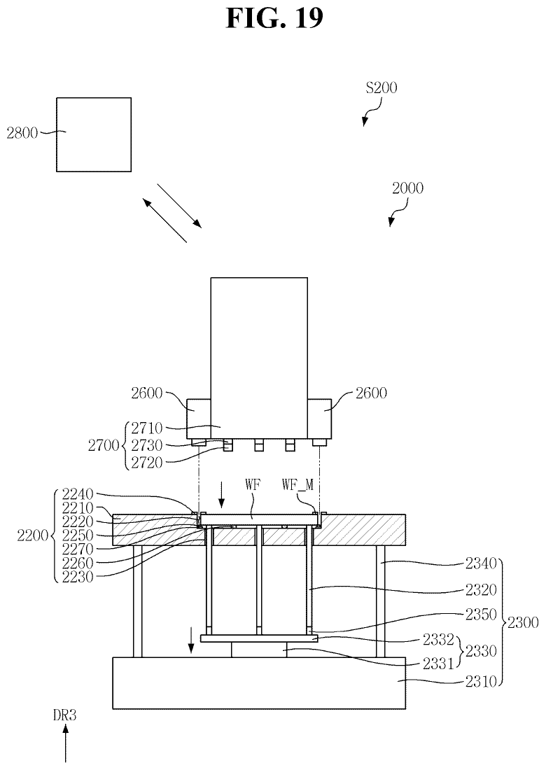

FIGS. 18 and 19 are cross-sectional views showing process S200 of FIG. 16.

Referring to FIGS. 18 and 19 in addition to FIGS. 15 and 16, in the wafer primary alignment and mounting process (process S200), the wafer transfer unit 2500 (see FIG. 11) may receive a driving signal from the alignment processing unit 2810 of the controller 2800 to locate the wafer WF on the carrier 2200.

The second vision device 2600 may receive a driving signal from the alignment processing unit 2810 of the controller 2800 to capture images of the carrier mark 2240 of the carrier 2200 and the wafer mark WF_M of the wafer WF. The second vision device 2600 may provide the captured images to the alignment processing unit 2810 of the controller 2800.

The alignment processing unit 2810 may determine whether or not the carrier 2200 and the wafer WF are properly aligned with each other based on the images captured by first vision device 2400 and provided thereto. The alignment processing unit 2810 may provide a driving signal to the wafer transfer unit 2500 (see FIG. 11) in real time to align the wafer WF with the carrier 2200.

When the carrier 2200 and the wafer WF are correctly or properly aligned with each other, the pin driver 2330 of the alignment unit 2300 may receive a driving signal from the alignment processing unit 2810 and move in the third direction DR3. Accordingly, the wafer WF may be mounted on the pins 2320.

When the wafer WF is mounted on the pin 2320, the pin driver 2330 of the alignment unit 2300 may receive a driving signal from the alignment processing unit 2810 and move in the opposite direction of the third direction DR3. Accordingly, the wafer WF may be mounted in the wafer accommodating portion 2220 of the carrier 2200.

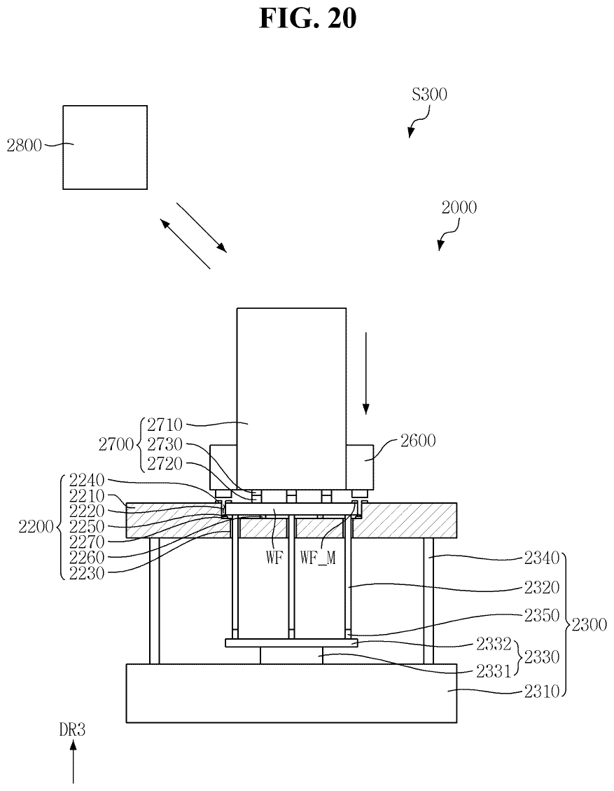

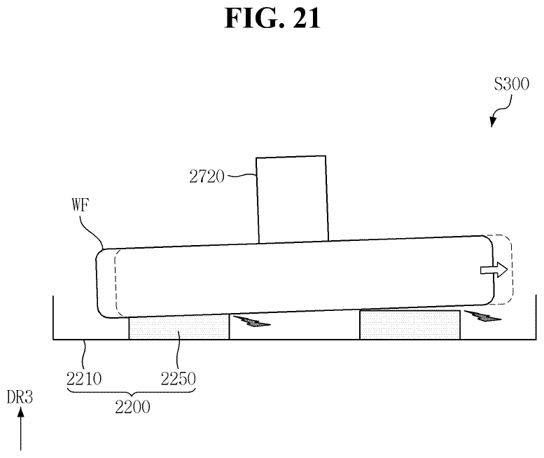

FIGS. 20 and 21 are cross-sectional views showing process S300 of FIG. 16.

Referring to FIGS. 20 and 21 in addition to FIGS. 15 and 16, in the wafer primary pressing process (process S300), the pressing unit 2700 may receive a driving signal from the pressing processing unit 2830 and move in the opposite direction of the third direction DR3. Accordingly, the pressing part 2720 of the pressing unit 2700 may press the top surface of the wafer WF mounted on the carrier 2200.

At the same time with the pressing, the second pressure sensor 2730 of the pressing unit 2700 may provide the pressing force applied to the pressing part 2720 to the pressing processing unit 2830 in real time. The pressing processing unit 2830 may store first pressing data that is preset such that the pressing unit 2700 may apply an appropriate pressing force to the wafer WF when the wafer WF and the carrier 2200 are coupled to each other. The first pressing data may include information on a maximum pressure and a pressing time at the time of coupling the wafer WF and the carrier 2200. The pressing processing unit 2830 may provide the first pressing data to the pressing unit 2700 in real time such that the pressing unit 2700 may press the wafer WF with an appropriate pressing force. Accordingly, damage to the wafer WF may be effectively prevented.

In an embodiment, as shown in FIG. 21, a slip phenomenon may occur when the wafer WF is pressed depending on the pressing angle of the pressing part 2720, the thickness difference of the coupling portion 2250, the friction force between the wafer WF and the coupling portion 2250, or the like. Accordingly, the alignment of the wafer WF and the carrier 2200 may be distorted.

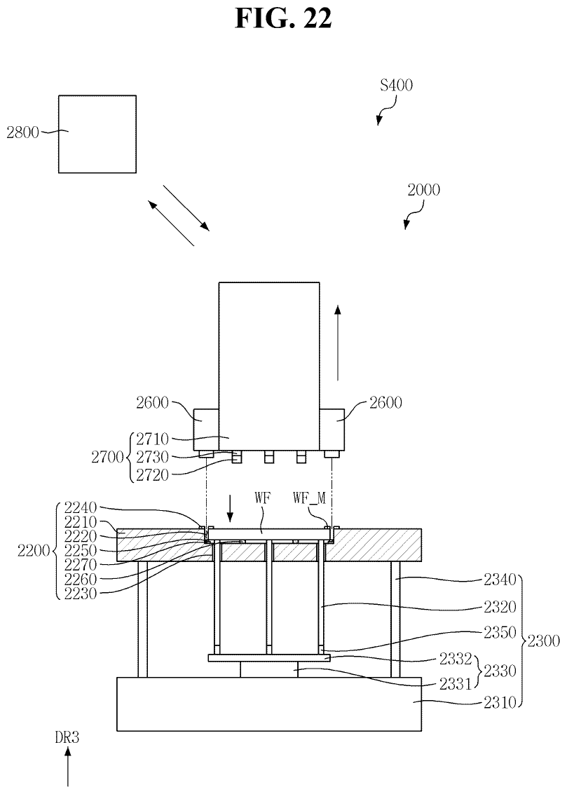

FIG. 22 is a cross-sectional view showing process S400 of FIG. 16. FIG. 23 is a plan view illustrating an embodiment of a method of measuring a degree of distortion of a wafer.

Referring to FIGS. 22 and 23 in addition to FIGS. 15 and 16, in the primary distortion inspection process (process S400), the pressing unit 2700 may receive a driving signal from the pressing processing unit 2830 and move in the third direction DR3.

After the primary pressing process, the second vision device 2600 may receive a driving signal from the alignment correction value calculation unit 2820 of the controller 2800 to capture images of the carrier mark 2240 of the carrier 2200 and the wafer mark WF_M of the wafer WF again. The second vision device 2600 may provide the re-captured images to the alignment correction value calculation unit 2820 of the controller 2800.

The alignment correction value calculation unit 2820 may calculate a degree of distortion of the wafer WF based on the images captured by the second vision device 2600 and provided thereto after pressing by comparing the image captured before pressing with the image captured after pressing.

As shown in FIG. 23, a wafer WF″ after pressing may be distorted to a certain level compared to a wafer WF′ before pressing. In an embodiment, for example, a center C″ of the wafer WF″ after pressing may be shifted from the center C′ of the wafer WF′ before pressing by x in the first direction DR1 and by y in the second direction DR2. Further, the wafer WF″ after pressing may be rotated by θ compared to the wafer WF′ before pressing.

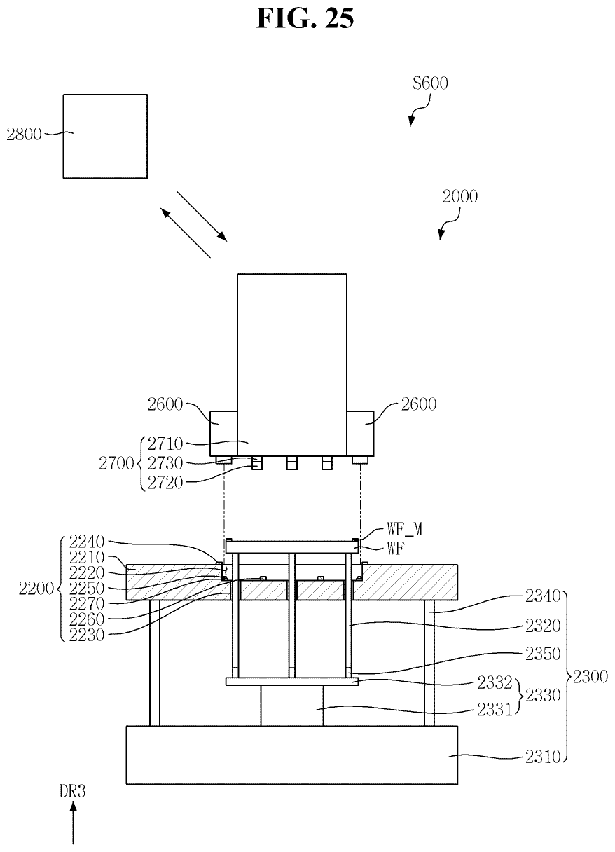

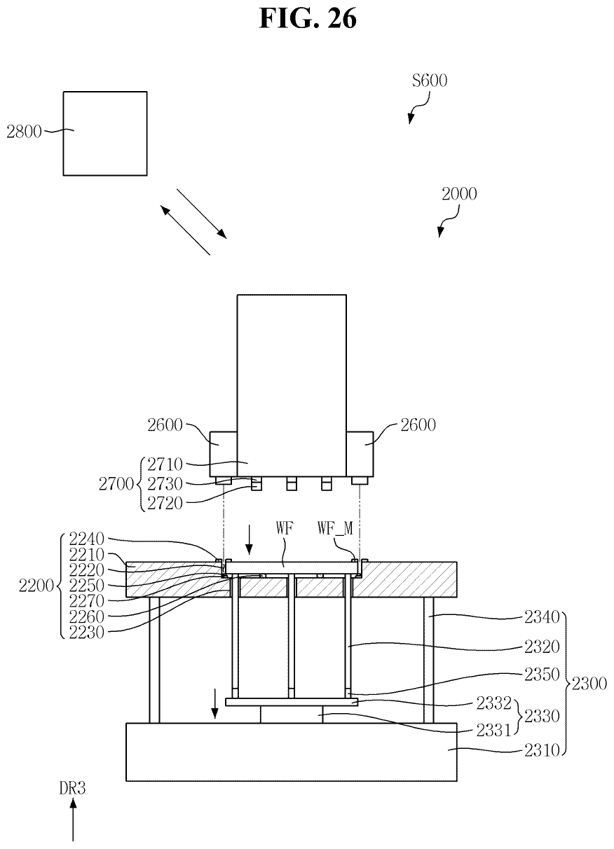

The alignment correction value calculation unit 2820 may convert a degree of distortion of (x, y, θ) to a correction value of (−x, −y, −θ). The alignment correction value calculation unit 2820 may provide the correction value of (−x, −y, −θ) to the alignment unit 2300. The alignment unit 2300 may use the correction value in the wafer secondary alignment and mounting process (process S600). This will be described together with the description of the wafer secondary alignment and mounting process (process S600) with reference to FIGS. 25 and 26.

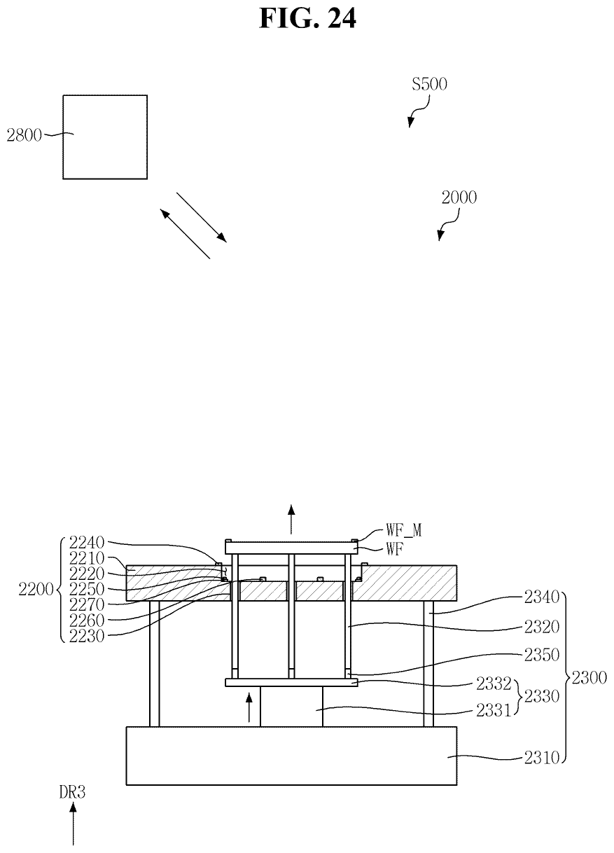

FIG. 24 is a cross-sectional view showing process S500 of FIG. 16.

Referring to FIG. 24 in addition to FIGS. 15 and 16, in the wafer detachment inspection process (process S500), the pin driver 2330 of the alignment unit 2300 may receive a driving signal from the detachment processing unit 2840 and move in the third direction DR3. Accordingly, the pin 2320 may press the bottom surface of the wafer WF coupled to the carrier 2200.

At the same time with the pressing, the first pressure sensor 2350 of the alignment unit 2300 may provide the pressing force applied to the pin 2320 to the detachment processing unit 2840 in real time. The detachment processing unit 2840 may store second pressing data that is preset so that the alignment unit 2300 may apply an appropriate pressing force to the wafer WF when the wafer WF is detached. The second pressing data may include information on a maximum pressure and a pressing time at the time of detaching the wafer WF. The detachment processing unit 2840 may provide the second pressing data to the alignment unit 2300 in real time such that the alignment unit 2300 may press the wafer WF with an appropriate pressing force. Accordingly, damage to the wafer WF may be effectively prevented.

The display device manufacturing method S1 according to an embodiment includes the wafer detachment inspection process (process S500), such that process loss that occurs when the wafer WF is not detached after the manufacturing process of the display device is completely ended or when damages are caused by detachment is inspected in advance. Accordingly, a detachment defective wafer WF may be selected in advance, thereby minimizing the process loss.

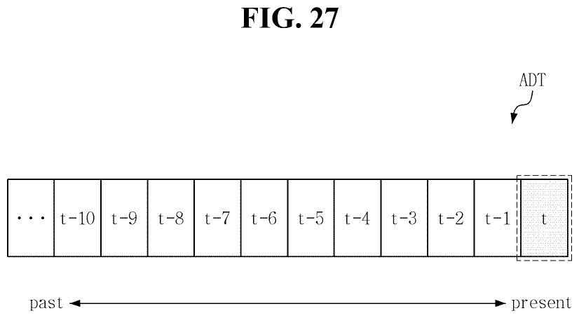

FIGS. 25 and 26 are cross-sectional views showing process S600 of FIG. 16. FIG. 27 is a schematic diagram illustrating alignment correction data processed by a controller.

Referring to FIGS. 25 to 27 in addition to FIGS. 15, 16, and 23, in the wafer secondary alignment and mounting process (process S600), the alignment unit 2300 may receive the alignment correction value from the alignment correction value calculation unit 2820 of the controller 2800.

The alignment unit 2300 may shift the wafer WF from the previous alignment position (e.g., the center C′ of the wafer WF′ before pressing) based on the alignment correction value provided thereto from the alignment correction value calculation unit 2820 of the controller 2800 by the above-described correction value of (−x, −y, −θ) to align the wafer WF on the carrier 2200.

During the process in which the alignment unit 2300 aligns the wafer WF on the carrier 2200 by shifting by the alignment correction value, the second vision device 2600 may provide the captured images of the carrier mark 2240 and the wafer mark WF_M of the wafer WF to the alignment correction value calculation unit 2820 in real time. The alignment processing unit 2810 may provide a driving signal to the alignment unit 2300 based on the images from the second vision device 2600 to adjust the position and the rotation angle of the wafer WF.

When the carrier 2200 and the wafer WF are shifted by the correction value and correctly aligned with each other, the pin driver 2330 of the alignment unit 2300 may receive a driving signal from the alignment correction value calculation unit 2820 and move in the opposite direction of the third direction DR3. Accordingly, the wafer WF may be mounted in the wafer accommodating portion 2220 of the carrier 2200.

In an embodiment, as shown in FIG. 27, alignment correction value data ADT provided to the alignment unit 2300 by the alignment correction value calculation unit 2820 may include alignment correction values t-10 to t-1 of previous wafers WF and a correction value t of a current wafer WF. The correction value t of the current wafer WF refers to the correction value of (−x, −y, −θ) calculated by the alignment correction value calculation unit 2820 after the primary pressing of the current wafer WF. The alignment correction values t-10 to t-1 of the previous wafers WF will be described later with reference to FIG. 30.

In the wafer secondary alignment and mounting process (process S600), the secondary alignment of the wafer WF may be performed using only the correction value t of the current wafer WF without using the alignment correction values t-10 to t-1 of the previous wafers WF.

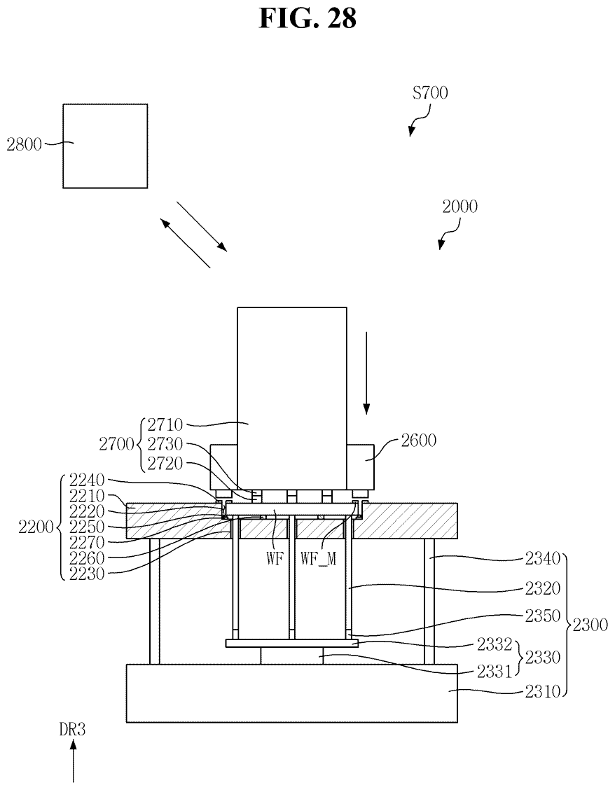

FIG. 28 is a cross-sectional view showing process S700 of FIG. 16.

Referring to FIG. 28 in addition to FIGS. 15 and 16, in the wafer secondary pressing process (process S700), the pressing unit 2700 may press the wafer WF. Since the wafer secondary pressing process (process S700) is substantially the same as the wafer primary pressing process (process S300) described with reference to FIG. 20, any repetitive detailed description of the same or like elements as those described above will be omitted.

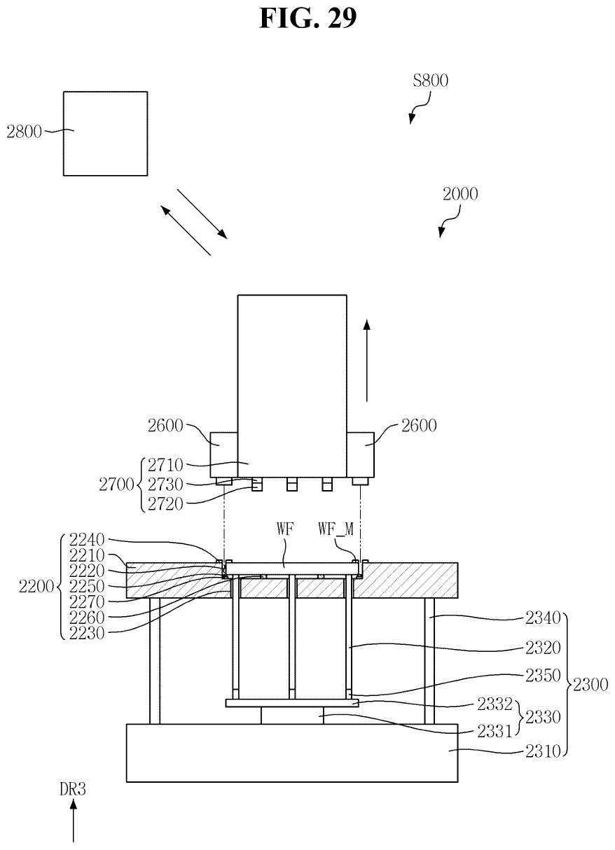

FIG. 29 is a cross-sectional view showing process S800 of FIG. 16.

Referring to FIG. 29 in addition to FIGS. 15 and 16, in the secondary distortion inspection process (process S800), the pressing unit 2700 may receive a driving signal from the pressing processing unit 2830 and move in the third direction DR3.

After the secondary pressing process, the second vision device 2600 may receive a driving signal from the alignment correction value calculation unit 2820 of the controller 2800 to capture images of the carrier mark 2240 of the carrier 2200 and the wafer mark WF_M of the wafer WF again. The second vision device 2600 may provide the re-captured images to the alignment correction value calculation unit 2820 of the controller 2800.

The alignment correction value calculation unit 2820 may calculate a degree of distortion of the wafer WF after pressing based on the image provided thereto from the second vision device 2600 by comparing the image captured before pressing with the image captured after pressing.

When a degree of distortion of the wafer WF before the primary pressing and the wafer WF after the secondary pressing is smaller than or equal to a threshold (OK), the display device manufacturing method S1 according to an embodiment is ended.

On the other hand, when a degree of distortion of the wafer WF before the primary pressing and the wafer WF after the secondary pressing exceeds the threshold (NG), the alignment correction value recalculation and wafer realignment process (process S900) is performed.

In some embodiments, the threshold may be in a range of about 10 micrometers (μm) to about 50 μm. In an embodiment, for example, where the threshold is 10 μm, when a degree of distortion of the wafer WF before the primary pressing and the wafer WF after the secondary pressing is 10 μm or less, the display device manufacturing method S1 according to an embodiment is ended, and when a degree of distortion of the wafer WF before the primary pressing and the wafer WF after the secondary pressing exceeds 10 am, the alignment correction value recalculation and wafer realignment process (process S900) is performed. Alternatively, in another embodiment where the threshold is 30 am, when a degree of distortion of the wafer WF before the primary pressing and the wafer WF after the secondary pressing is 30 μm or less, the display device manufacturing method S1 according to an embodiment is ended, and when a degree of distortion of the wafer WF before the primary pressing and the wafer WF after the secondary pressing exceeds 30 μm, the alignment correction value recalculation and wafer realignment process (process S900) is performed. The threshold may be set variously within a range of about 10 μm to about 50 m depending on process conditions of the display device manufacturing method S1 according to an embodiment.

Hereinafter, when a degree of distortion of the wafer WF before the primary pressing and the wafer WF after the secondary pressing exceeds the threshold (NG), the alignment correction value recalculation and wafer realignment process (process S900) will be described with reference to FIG. 30.

FIG. 30 is a cross-sectional view showing process S900 of FIG. 16.

Referring to FIG. 30 in addition to FIGS. 15 and 16, in the alignment correction value recalculation process (process S910), the alignment correction value calculation unit 2820 may recalculate the alignment correction value. The wafer realignment and mounting process (process S920), the wafer re-pressing process (process S930), and the distortion re-inspection process (process S940) may be performed using the recalculated alignment correction value.

The wafer realignment and mounting process (process S920), the wafer re-pressing process (process S930), and the distortion re-inspection process (process S940) are substantially the same as the wafer secondary alignment and mounting process (process S600) described with reference to FIGS. 25 and 26, the wafer secondary pressing process (process S700) described with reference to FIG. 28, and the secondary distortion inspection process (process S800) described with reference to FIG. 29, respectively, and any repetitive detailed description of the same or like elements as those described above will be omitted.

In the distortion re-inspection process (process S940), when a degree of distortion of the wafer WF before the primary pressing and the wafer WF after the re-pressing is smaller than or equal to the threshold (OK), the display device manufacturing method S1 according to an embodiment is ended.

In such a process, when a degree of distortion of the wafer WF before the primary pressing and the wafer WF after re-pressing exceeds the threshold (NG), the alignment correction value recalculation and wafer realignment process (process S900) is repeatedly performed.

More specifically, in the alignment correction value recalculation process (process S910), unlike the wafer secondary alignment and mounting process (process S600), the alignment correction values t-10 to t-1 of the previous wafers WF included in the alignment correction value data ADT may be further used.

The alignment correction values t-10 to t-1 of the previous wafers WF may each include sub-correction values. In an embodiment, for example, the (t-1)^{th} alignment correction value includes sub-correction values Sₜ₋₁1, Sₜ₋₁2, Sₜ₋₁3, and Sₜ₋₁4, the (t-2)^{th} alignment correction value includes sub-correction values Sₜ₋₂1 and Sₜ₋₂2, and the (t-3)^{th} alignment correction value includes sub-correction values Sₜ₋₃1, Sₜ₋₃2, and Sₜ₋₃3.

The number of sub-correction values included in the respective alignment correction values t-10 to t-1 may be equal to the number of correction value calculations for the respective wafers WF, that is, the number of repetitions of the alignment correction value recalculation process (process S910). In an embodiment, for example, the correction values calculated in the primary distortion inspection process (process S400) may be first sub-correction values Sₜ1, Sₜ₋₁1, Sₜ₋₂1, Sₜ₋₃1, . . . of the respective alignment correction values t-10 to t-1. Second and subsequent sub-correction values Sₜ2, Sₜ₋₁2, Sₜ₋₂2, Sₜ₋₃2, . . . may be correction values calculated in the secondary distortion inspection process (process S800) or the distortion re-inspection process (process S940). The final sub-correction values Sₜ₋₁₀, Sₜ₋₉, Sₜ₋₈, . . . , Sₜ₋₃₃, Sₜ₋₂2, Sₜ₋₁4 included in the alignment correction values t-10 to t-1 of the previous wafers WF may be final correction values obtained when a degree of distortion of the wafer WF is smaller than or equal to the threshold in the secondary distortion inspection process (process S800) or the distortion re-inspection process (process S940).

When a degree of distortion of the wafer WF exceeds the threshold in the secondary distortion inspection process (process S800) of the current wafer WF, the alignment correction value calculation unit 2820 may use the average value of the correction values t-10 to t-1 of the previous wafers WF as a new correction value (e.g., Sₜ2) in a first cycle R1. In an embodiment, for example, the average value of the (t-10)^{th} alignment correction value to the (t-1)^{th} alignment correction value may be used as a new correction value.

When a degree of distortion of the wafer WF exceeds the threshold in the distortion re-inspection process (process S940) of the first cycle R1, the alignment correction value calculation unit 2820 may use the average value of the alignment correction values t-9 to t-1 of the previous wafers WF and the previous sub-correction value Sₜ1 of the current wafer WF as a new correction value (e.g., Sₜ3) in a second cycle R2. In an embodiment, for example, the average value of the (t-9)^{th} alignment correction value to the (t-1)^{th} alignment correction value and the Sₜ1^{th} sub-alignment correction value may be used as a new correction value.

When a degree of distortion of the wafer WF exceeds the threshold in the distortion re-inspection process (process S940) of the second cycle R2, the alignment correction value calculation unit 2820 may use the average value of the alignment correction values t-8 to t-1 of the previous wafers WF and the previous sub-correction values Sₜ1 and Sₜ2 of the current wafer WF as a new correction value in a third cycle R3. In an embodiment, for example, the average value of the (t-8)^{th} alignment correction value to the (t-1)^{th} alignment correction value, the Sₜ1^{th} sub-alignment correction value, and the Sₜ2^{th} sub-alignment correction value may be used as a new correction value.

In an embodiment, a new correction value may be calculated using ten previous alignment correction values as shown in FIG. 30, but the disclosure is not limited thereto. In another embodiment, the number of previous alignment correction values used to calculate a new correction value may be variously changed.

In the display device manufacturing method S1 according to embodiments, it may be possible to minimize the distortion of the wafer WF by reflecting the correction value calculated by the primary distortion inspection in advance in the secondary pressing process carried out after the detachment inspection of the wafer WF.

In such embodiments, when the wafer WF is distorted even after the secondary pressing, the correction value is newly calculated using the alignment correction values t-10 to t-1 of the previous wafers WF, such that the alignment process of the wafer WF and the carrier 2200 may be quickly performed, and the alignment accuracy of the wafer WF and the carrier 2200 may be improved.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An apparatus for manufacturing a display device, the apparatus comprising:
an alignment unit;
a carrier disposed on the alignment unit, wherein the carrier comprises an accommodating portion in which a wafer is accommodated;
a pressing unit disposed on the carrier;
a first vision device disposed on one side of the pressing unit on the carrier; and
a controller which controls an alignment of the wafer and the carrier.

2. The apparatus of claim 1, wherein
the carrier further comprises a first alignment mark disposed on one side of the accommodating portion, and
the first vision device captures images of the first alignment mark of the carrier and a second alignment mark of the wafer.

3. The apparatus of claim 2, wherein
the first vision device comprises a camera, and
a number of the camera in the first vision device is equal to a number of the first alignment mark in the carrier.

4. The apparatus of claim 1, wherein
the carrier further comprises a coupling portion disposed on a bottom surface of the accommodating portion,
the coupling portion is disposed between the wafer and the carrier, and
the wafer and the carrier are coupled to each other by the coupling portion.

5. The apparatus of claim 4, wherein the coupling portion comprises a sticky chuck or an electrostatic chuck.

6. The apparatus of claim 4, wherein the carrier further comprises:
a buffer portion disposed on a portion of the bottom surface of the accommodating portion other than a portion where the coupling portion is disposed; and
a step compensation portion disposed below the coupling portion,
wherein a thickness of the buffer portion is equal to a sum of a thickness of the coupling portion and a thickness of the step compensation portion.

7. The apparatus of claim 1, wherein
the alignment unit comprises a pin extending in a direction toward the carrier,
the a pin hole is defined through the carrier in a lower portion of the accommodating portion, and
the pin moves through the pin hole.

8. The apparatus of claim 7, wherein the wafer is mounted on the pin.

9. The apparatus of claim 7, wherein
the alignment unit further comprises a pin driver disposed below the pin, and
the pin driver comprises a vertical driver and a rotational driver.

10. The apparatus of claim 7, wherein
the alignment unit further comprises a first pressure sensor disposed below the pin, and
the first pressure sensor measures a pressing force applied thereto when detaching the wafer from the carrier.

11. The apparatus of claim 10, wherein
the pin is provided in plurality, and
the first pressure sensor is provide in plurality in a one-to-one correspondence with the plurality of pins.

12. The apparatus of claim 1, wherein the pressing unit comprises:
a pressing part disposed on a first surface facing the carrier; and
a second pressure sensor disposed between the first surface and the pressing part, and
wherein the second pressure sensor measures a pressing force applied thereto when coupling the carrier and the wafer to each other.

13. The apparatus of claim 1, wherein
the first vision device captures a first image after a primary alignment of the wafer and before a primary pressing of the wafer, and captures a second image after the primary pressing of the wafer,
the controller comprises an alignment correction value calculation unit,
the alignment correction value calculation unit calculates a correction value by comparing the first image with the second image, and
the alignment unit aligns the wafer to be shifted by the correction value during a secondary pressing of the wafer.

14. The apparatus of claim 1, further comprising a second vision device disposed on the carrier, wherein the second vision device captures images of the carrier and the alignment unit.

15. The apparatus of claim 1, further comprising a carrier transfer unit which positions the carrier on the alignment unit.

16. The apparatus of claim 1, further comprising a wafer transfer unit which positions the wafer on the carrier.

17. The apparatus of claim 16, wherein
the controller comprises an alignment processing unit,
the alignment processing unit provides a driving signal to the wafer transfer unit,
the wafer transfer unit positions the wafer on the carrier based on the driving signal,
the first vision device provides captured images of the carrier and the wafer to the alignment processing unit, and
the alignment processing unit provides the driving signal again to the wafer transfer unit based on the captured images to align the wafer with the carrier in real time.

18. The apparatus of claim 1, wherein in a plan view, the carrier has a quadrilateral shape, and the wafer has a circular shape.

19. A method of manufacturing a display device, the method comprising:
performing a primary alignment process including aligning a wafer with a reference point of a carrier;
performing a wafer primary pressing process including pressing the wafer;
performing a primary distortion inspection process including measuring a first degree of distortion of the wafer and the carrier;
performing a detachment process including detaching the wafer from the carrier;
performing a secondary alignment process including aligning the wafer with the carrier;
performing a wafer secondary pressing process including pressing the wafer; and
performing a secondary distortion inspection process including measuring a second degree of distortion of the wafer and the carrier,
wherein the performing the secondary alignment process comprises aligning the wafer to be shifted from the reference point by a correction value by using the first degree of distortion measured in the primary distortion inspection process as the correction value.

20. The method of claim 19, wherein when the second degree of distortion is smaller than or equal to a threshold in the secondary distortion inspection process, the method is ended.

21. The method of claim 19, wherein when the second degree of distortion exceeds a threshold in the secondary distortion inspection process, method further comprises performing a correction value recalculation and wafer realignment process including recalculating the correction value and realigning the wafer.

22. The method of claim 21, wherein the performing the correction value recalculation and wafer realignment process comprises:
performing a correction value recalculation process including recalculating the correction value;
performing a wafer realignment process including realigning the wafer;
performing a process including re-pressing the wafer; and
performing a distortion re-inspection process including measuring a third degree of distortion of the wafer and the carrier.

23. The method of claim 22, wherein the performing the correction value recalculation process comprises calculating a correction value of a current wafer using correction values of previous wafers.

24. The method of claim 23, wherein when the third degree of distortion is smaller than or equal to a threshold in the distortion re-inspection process, the method is ended.

25. The method of claim 23, wherein when the third degree of distortion exceeds a threshold in the distortion re-inspection process, the method further comprises performing the correction value recalculation and wafer realignment process again.

26. The method of claim 25, wherein
each of correction values of previous wafers comprises at least one sub-correction value, and
a number of sub-correction values in the correction values of the previous wafers is equal to a number of repetitions of the performing the correction value recalculation process.

27. The method of claim 26, wherein a final sub-correction value among the sub-correction values in each correction value of the previous wafers is a correction value of the previous wafers.

28. The method of claim 19, wherein in each of the performing the wafer primary pressing process and the performing the wafer secondary pressing process, a combined pressing force is corrected in real time based on a pressing force measured by a pressure sensor.

29. The method of claim 19, wherein in the performing the detachment process including the detaching the wafer from the carrier, a detachment pressing force is corrected in real time based on a pressing force measured by a pressure sensor.

30. An electronic device comprises a head mounted display device manufactured by the apparatus of claim 1,
wherein the head mounted display device comprises:
at least one display device;
a display device housing configured to accommodate the at least one display device; and
an optical member configured to magnify a display image of the at least one display device or change an optical path,
wherein the at least one display device comprises:
a semiconductor substrate;
a plurality of conductive layers sequentially stacked on the semiconductor substrate; and
a plurality of light emitting elements on the plurality of conductive layers.

31. An electronic device comprises a head mounted display device manufactured by the method of claim 19,
wherein the head mounted display device comprises:
at least one display device;
a display device housing configured to accommodate the at least one display device; and
an optical member configured to magnify a display image of the at least one display device or change an optical path,
wherein the at least one display device comprises:
a semiconductor substrate;
a plurality of conductive layers sequentially stacked on the semiconductor substrate; and
a plurality of light emitting elements on the plurality of conductive layers.
